(19) United States
(12) Patent Application Publication
(10) Pub. No.: US 2025/0153670 A1
(43) Pub. Date: May 15, 2025

(54) METHOD AND APPARATUS FOR CONTROLLING ROLLOVER PREVENTION OF TANK TRUCK, CLOUD, TANK TRUCK, AND SYSTEM FOR CONTROLLING ROLLOVER PREVENTION OF TANK TRUCK

(71) Applicant: TSINGHUA UNIVERSITY, Beijing (CN)

(72) Inventors: Bolin GAO, Beijing (CN); Xiaojing QI, Beijing (CN)

(21) Appl. No.: 19/021,266

(22) Filed: Jan. 15, 2025

Related U.S. Application Data
(63) Continuation of application No. PCT/CN2024/074212, filed on Jan. 26, 2024.

(30) Foreign Application Priority Data
Sep. 25, 2023 (CN) 202311239283.0
Sep. 25, 2023 (CN) 202311247016.8

(51) Int. Cl. B60R 21/013; B60R 21/00; B60R 21/01; B60R 21/0132

(52) U.S. Cl. CPC B60R 21/013; B60R 2021/0018; B60R 2021/0074; B60R 2021/01013; B60R 2021/01322

(57) ABSTRACT

Provided are a method and apparatus for controlling rollover prevention of a tank truck, a cloud, a tank truck, and a system for controlling rollover prevention of a tank truck. The method includes: obtaining vehicle information sent by the tank truck and liquid filling information obtained based on a sensor; inputting the vehicle information and the liquid filling information into a vehicle fine model and a liquid sloshing fine model respectively, and outputting a first parameter calibration result and a second parameter calibration result respectively; and transmitting the first parameter calibration result and the second parameter calibration result to the tank truck, determining a control target of the tank truck by combining vehicle state sensor information observation and liquid related sensor information observation, and controlling the rollover prevention of the tank truck based on the control target.

### CROSS-REFERENCE TO RELATED APPLICATION

This application is a continuation of International Patent Application No. PCT/CN2024/074212, filed on Jan. 26, 2024, which is based on and claims priorities to Chinese Patent Applications Nos. 202311247016.8 and 202311239283.0 filed on Sep. 25, 2023, the entire contents of which are incorporated herein by reference.

### FIELD

The present disclosure relates to the field of autonomous driving technologies, and more particularly, to a method and apparatus for controlling rollover prevention of a tank truck, a cloud, a tank truck, and a system for controlling rollover prevention of a tank truck.

### BACKGROUND

A commercial tank truck is a common vehicle for delivering hazardous chemicals. Since it can only be not fully loaded according to the standard, the liquid in the commercial tank truck is easy to slosh. In addition, since a center of mass is high and a load is heavy, rollover stability after vehicle-liquid coupling is unsatisfactory, which is prone to cause rollover accidents, resulting in leakage of hazardous chemicals or even explosion. In the future intelligent vehicle cyber-physical system, manual tank truck driving for a pure transportation purpose, which is highly dangerous and labor-intensive, will be replaced by automatic driving. For an automatic commercial tank truck, it is extremely important to predict liquid sloshing and reasonably control a lateral acceleration of the vehicle based on the liquid sloshing.

The most accurate method to describe liquid sloshing is a CFD (Computational Fluid Dynamics) method. However, a finite element model has a large amount of calculation and is far from real-time. Also, a simplified surrogate model can be established based on a vehicle and a liquid sloshing mechanism, an algorithm for controlling rollover prevention considering the liquid sloshing can be designed based on a vehicle model and a liquid model, and measurement or estimation of state variables required for control can be realized based on a surrogate model.

However, parameters in the surrogate model will change with variation of liquid filling conditions. Each change requires a large amount of finite element calculations to calibrate a liquid surrogate model, and a computation power of the vehicle side cannot support such a large amount of calculations.

### SUMMARY

The present disclosure provides a method and apparatus for controlling rollover prevention of a tank truck, a cloud, a tank truck, and a system for controlling rollover prevention of a tank truck, aiming at solving problems in the related art such as an inability to realize rollover prevention of the tank truck through real-time calculation and an inability to support a huge calculation amount.

In a first aspect, a method for controlling rollover prevention of a tank truck is provided according to embodiments of the present disclosure. The method is applied to a cloud and includes: obtaining vehicle information sent by the tank truck and liquid filling information obtained based on a sensor; inputting the vehicle information and the liquid filling information into a vehicle fine model and a liquid sloshing fine model respectively, where the vehicle fine model outputs a first parameter calibration result, and the liquid sloshing fine model outputs a second parameter calibration result; and transmitting the first parameter calibration result and the second parameter calibration result to the tank truck, where the tank truck calibrates a vehicle surrogate model and a liquid surrogate model by using the first parameter calibration result and the second parameter calibration result respectively, determines a control target of the tank truck by combining vehicle state sensor information observation and liquid related sensor information observation, and controls the rollover prevention of the tank truck based on the control target.

In another exemplary embodiment of the present disclosure, the vehicle fine model is a multi-body dynamics model. The liquid sloshing fine model is a finite element model. The vehicle surrogate model is a linear simplified dynamics model. The liquid surrogate model is an equivalent pendulum dynamics model.

In another exemplary embodiment of the present disclosure, the method further includes, prior to inputting the vehicle information and the liquid filling information into the vehicle fine model and the liquid sloshing fine model respectively: obtaining a multi-degree-of-freedom equivalent pendulum model of liquid sloshing in a tank of the tank truck; setting a specific structure and an input variable of the multi-degree-of-freedom equivalent pendulum model, and determining kinetic energy and potential energy of the multi-degree-of-freedom equivalent pendulum model based on the specific structure and the input variable; determining a differential dynamics equation of a plurality of swing degrees of freedom based on the kinetic energy and the potential energy of the multi-degree-of-freedom equivalent pendulum model, and identifying all undetermined parameters of the differential dynamics equation based on an established liquid sloshing model for a cross-section of the tank; and constructing a simplified liquid sloshing model for the tank of the tank truck based on the differential dynamics equation and all the undetermined parameters.

In another exemplary embodiment of the present disclosure, said obtaining the multi-degree-of-freedom equivalent pendulum model of liquid sloshing in the tank of the tank truck includes: taking a pendulum rod and a lumped mass as basic units; hinging an end of the pendulum rod to a point or a lumped mass in the cross-section of the tank; determining a motion track of the lumped mass connected by the pendulum rod without a fixing end as a part of an ellipse; and allowing the lumped mass to hinge a plurality of pendulum rods, and allowing one or more lumped masses to be fixed to a point in the cross-section of the tank with the one or more lumped masses not connecting any pendulum rod to establish the multi-degree-of-freedom equivalent pendulum model.

In another exemplary embodiment of the present disclosure, the specific structure includes a linear and/or non-linear combination of at least a plurality of simple pendulums and/or elliptical pendulums.

In another exemplary embodiment of the present disclosure, said determining the kinetic energy and potential energy of the multi-degree-of-freedom equivalent pendulum model based on the specific structure and the input variable includes: setting an acting point and a positive direction of an output force and a torque of the multi-degree-of-freedom equivalent pendulum model in the cross-section of the tank, and establishing a plane rectangular coordinate system by taking the acting point as an origin and taking the positive direction as a coordinate axis; expressing a position vector of each lumped mass of the multi-degree-of-freedom equivalent pendulum model in the plane rectangular coordinate system, and calculating a first derivative and a second derivative of the position vector of each lumped mass with respect to time to obtain a velocity vector and an acceleration vector of each lumped mass; and determining the kinetic energy of the multi-degree-of-freedom equivalent pendulum model and potential energy of the kinetic energy of the multi-degree-of-freedom equivalent pendulum model at a designated zero potential energy point by using the position vector, the velocity vector, and the acceleration vector.

In another exemplary embodiment of the present disclosure, said identifying all undetermined parameters of the differential dynamics equation based on the established liquid sloshing model for the cross-section of the tank includes: setting a plurality of output variables of the liquid sloshing model and an output mode for the output variables; obtaining output variable time series data of the plurality of output variables based on a predetermined operation condition, and constructing a cost function of an undetermined parameter of the differential dynamics equation based on the output mode for the output variables and the output variable time series data; and optimizing the cost function and identifying all undetermined parameters of the differential dynamics equation based on the optimized cost function.

In another exemplary embodiment of the present disclosure, the output variables include a lateral force, a vertical force, and a roll torque. The predetermined operation condition includes a lateral acceleration step excitation operation condition and/or a lateral acceleration sinusoid fluctuation operation condition. The cost function is a non-negative weighted sum of all error terms.

In a second aspect, a method for controlling rollover prevention of a tank truck is provided according to embodiments of the present disclosure. The method is applied to the tank truck and includes: sending vehicle information and liquid filling information obtained based on a sensor to a cloud, where the cloud inputs the vehicle information and the liquid filling information into a vehicle fine model and a liquid sloshing fine model respectively, and where the vehicle fine model outputs a first parameter calibration result and the liquid sloshing fine model outputs a second parameter calibration result; obtaining the first parameter calibration result and the second parameter calibration result transmitted from the cloud, calibrating a vehicle surrogate model and a liquid surrogate model by using the first parameter calibration result and the second parameter calibration result respectively; and determining a control target of the tank truck by combining vehicle state sensor information observation and liquid related sensor information observation, and controlling the rollover prevention of the tank truck based on the control target.

In another exemplary embodiment of the present disclosure, said determining the control target of the tank truck by combining the vehicle state sensor information observation and the liquid related sensor information observation includes: estimating a first state variable of the vehicle surrogate model based on the vehicle state sensor information observation;

estimating a second state variable of the liquid surrogate model based on the liquid related sensor information observation; and determining the control target of the tank truck based on the first state variable and the second state variable.

In another exemplary embodiment of the present disclosure, said controlling the rollover prevention of the tank truck based on the control target includes: obtaining a first reference value of the vehicle surrogate model and a second reference value of the liquid surrogate model; determining a first error weight between an output variable of the vehicle surrogate model and the first reference value and a second error weight between an output variable of the liquid surrogate model and the second reference value; and applying the first error weight to the output variable of the vehicle surrogate model to realize a control target of trajectory tracking, applying the second error weight to the output variable of the liquid in surrogate model to realize a control target of sway suppression, and performing a soft constraint on a range of a part of output variables of the liquid surrogate model to realize a control target of rollover prevention.

In another exemplary embodiment of the present disclosure, the part of output variables to which the soft constraint is applied at least includes Iᵣₒₗᵢₒᵥₑᵣ. The output variable of the liquid surrogate model is y=[X₁ Y₁ ψ₁ θ \dot{θ} Iᵣₒₗᵢₒᵥₑᵣ], where X represents an x coordinate of a tractor in a world coordinate system, Y represents a y coordinate of the tractor in the world coordinate system, θ represents a swing angle of an equivalent pendulum model, \dot{θ} represents a swing angular velocity of the equivalent pendulum model, Iᵣₒₗₗₒᵥₑᵣ represents a state variable representing a rollover state of a vehicle, ψ₁ represents a heading angle of the tractor.

In another exemplary embodiment of the present disclosure, the state variable Iᵣₒₗₗₒᵥₑᵣ representing the rollover state of the vehicle uses a lateral load transfer ratio LTR_{eqt} equivalent to a suspension force:

$${LTR}_{eql} = \frac{2}{\frac{{T}_{w 1} + {T}_{w 2}}{2} ( {m}_{1} + {m}_{2} ) g} ( - {k}_{r 1} {ϕ}_{1} - {c}_{1} {\dot{ϕ}}_{1} - {k}_{r 2} {ϕ}_{2} - {c}_{2} {\dot{ϕ}}_{2} )$$

where, T_{w} represents an average track length of each axle, IN represents a mass of the vehicle, g represents an acceleration of gravity, kᵣ represents roll angle stiffness, C represents roll damping, ϕ represents a roll angle, \dot{ϕ} represents roll angular velocity, a subscript 1 represents the tractor, and a subscript 2 represents a trailer.

In a third aspect, an apparatus for controlling rollover prevention of a tank truck is provided according to embodiments of the present disclosure. The apparatus is applied to a cloud and includes: an obtaining module configured to obtain vehicle information sent by the tank truck and liquid filling information obtained based on a sensor; an input module configured to input the vehicle information and the liquid filling information into a vehicle fine model and a liquid sloshing fine model respectively, where the vehicle fine model outputs a first parameter calibration result, and the liquid sloshing fine model outputs a second parameter calibration result; and a transmitting module configured to transmit the first parameter calibration result and the second parameter calibration result to the tank truck, where the tank truck calibrates a vehicle surrogate model and a liquid surrogate model by using the first parameter calibration result and the second parameter calibration result respectively, determines a control target of the tank truck by combining vehicle state sensor information observation and liquid related sensor information observation, and controls the rollover prevention of the tank truck based on the control target.

In another exemplary embodiment of the present disclosure, the vehicle fine model is a multi-body dynamics model. The liquid sloshing fine model is a finite element model. The vehicle surrogate model is a linear simplified dynamics model. The liquid surrogate model is an equivalent pendulum dynamics model.

In another exemplary embodiment of the present disclosure, the input module further includes: an obtaining unit configured to obtain, prior to the vehicle information and the liquid filling information are inputted into the vehicle fine model and the liquid sloshing fine model respectively, a multi-degree-of-freedom equivalent pendulum model of liquid sloshing in a tank of the tank truck; a setting unit configured to set a specific structure and an input variable of the multi-degree-of-freedom equivalent pendulum model, and determine kinetic energy and potential energy of the multi-degree-of-freedom equivalent pendulum model based on the specific structure and the input variable; an determining unit configured to determine a differential dynamics equation of a plurality of swing degrees of freedom based on the kinetic energy and the potential energy of the multi-degree-of-freedom equivalent pendulum model, and identify all undetermined parameters of the differential dynamics equation based on an established liquid sloshing model for a cross-section of the tank; and a constructing unit configured to construct a simplified liquid sloshing model for the tank of the tank truck based on the differential dynamics equation and all the undetermined parameters.

In another exemplary embodiment of the present disclosure, the obtaining unit is further configured to: take a pendulum rod and a lumped mass as basic units; hinge an end of the pendulum rod to a point or a lumped mass in the cross-section of the tank; determine a motion track of the lumped mass connected by the pendulum rod without a fixing end as a part of an ellipse; and allow the lumped mass to hinge a plurality of pendulum rods, and allow one or more lumped masses to be fixed to a point in the cross-section of the tank with the one or more lumped masses not connecting any pendulum rod to establish the multi-degree-of-freedom equivalent pendulum model.

In another exemplary embodiment of the present disclosure, the specific structure includes a linear and/or non-linear combination of at least a plurality of simple pendulums and/or elliptical pendulums.

In another exemplary embodiment of the present disclosure, the setting unit is further configured to: set an acting point and a positive direction of an output force and a torque of the multi-degree-of-freedom equivalent pendulum model in the cross-section of the tank, and establish a plane rectangular coordinate system by taking the acting point as an origin and taking the positive direction as a coordinate axis; express a position vector of each lumped mass of the multi-degree-of-freedom equivalent pendulum model in the plane rectangular coordinate system, and calculate a first derivative and a second derivative of the position vector of each lumped mass with respect to time to obtain a velocity vector and an acceleration vector of each lumped mass; and determine the kinetic energy of the multi-degree-of-freedom equivalent pendulum model and potential energy of the kinetic energy of the multi-degree-of-freedom equivalent pendulum model at a designated zero potential energy point by using the position vector, the velocity vector, and the acceleration vector.

In another exemplary embodiment of the present disclosure, the determining unit is further configured to: set a plurality of output variables of the liquid sloshing model and an output mode for the output variables; obtain output variable time series data of the plurality of output variables based on a predetermined operation condition, and construct a cost function of an undetermined parameter of the differential dynamics equation based on the output mode for the output variables and the output variable time series data; and optimize the cost function and identify all undetermined parameters of the differential dynamics equation based on the optimized cost function.

In another exemplary embodiment of the present disclosure, the output variables include a lateral force, a vertical force, and a roll torque. The predetermined operation condition includes a lateral acceleration step excitation operation condition and/or a lateral acceleration sinusoid fluctuation operation condition. The cost function is a non-negative weighted sum of all error terms.

In a fourth aspect, an apparatus for controlling rollover prevention of a tank truck is provided according to embodiments of the present disclosure. The apparatus is applied to the tank truck and includes: a sending module configured to send vehicle information and liquid filling information obtained based on a sensor to a cloud, where the cloud inputs the vehicle information and the liquid filling information into a vehicle fine model and a liquid sloshing fine model respectively, and where the vehicle fine model outputs a first parameter calibration result and the liquid sloshing fine model outputs a second parameter calibration result; a calibration module configured to obtain the first parameter calibration result and the second parameter calibration result transmitted from the cloud, and calibrate a vehicle surrogate model and a liquid surrogate model by using the first parameter calibration result and the second parameter calibration result respectively; and a control module configured to determine a control target of the tank truck by combining vehicle state sensor information observation and liquid related sensor information observation, and control the rollover prevention of the tank truck based on the control target.

In another exemplary embodiment of the present disclosure, the control module is further configured to: estimate a first state variable of the vehicle surrogate model based on the vehicle state sensor information observation; estimate a second state variable of the liquid surrogate model based on the liquid related sensor information observation; and determine the control target of the tank truck based on the first state variable and the second state variable.

In another exemplary embodiment of the present disclosure, the control module is further configured to: obtain a first reference value of the vehicle surrogate model and a second reference value of the liquid surrogate model; determine a first error weight between an output variable of the vehicle surrogate model and the first reference value and a second error weight between an output variable of the liquid surrogate model and the second reference value; and apply the first error weight to the output variable of the vehicle surrogate model to realize a control target of trajectory tracking, apply the second error weight to the output variable of the liquid surrogate model to realize a control target of sway suppression, and perform a soft constraint on a range of a part of output variables of the liquid surrogate model to realize a control target of rollover prevention.

In another exemplary embodiment of the present disclosure, the part of output variables to which the soft constraint is applied at least includes Iᵣₒₗₗₒᵥₑᵣ. The output variable of the liquid surrogate model is y=[X₁ Y₁ ψ₁ θ \dot{θ} Iᵣₒₗₗₒᵥₑᵣ], where X represents an x coordinate of a tractor in a world coordinate system, Y represents a y coordinate of the tractor in the world coordinate system, θ represents a swing angle of an equivalent pendulum model, \dot{θ} represents a swing angular velocity of the equivalent pendulum model, Iᵣₒₗₗₒᵥₑᵣ represents a state variable representing a rollover state of a vehicle, ψ₁ represents a heading angle of the tractor.

In another exemplary embodiment of the present disclosure, the state variable Iᵣₒₗₗₒᵥₑᵣ representing the rollover state of the vehicle uses a lateral load transfer ratio LTR_{eql} equivalent to a suspension force:

$${LTR}_{eql} = \frac{2}{\frac{{T}_{w 1} + {T}_{w 2}}{2} ( {m}_{1} + {m}_{2} ) g} ( - {k}_{r 1} {ϕ}_{1} - {c}_{1} {\dot{ϕ}}_{1} - {k}_{r 2} {ϕ}_{2} - {c}_{2} {\dot{ϕ}}_{2} )$$

where, T_{w} represents an average track length of each axle, i represents a mass of the vehicle, g represents an acceleration of gravity, kᵣ represents roll angle stiffness, C represents roll damping, ϕ represents a roll angle, \dot{ϕ} represents roll angular velocity, a subscript 1 represents the tractor, and a subscript 2 represents a trailer.

In a fifth aspect, a cloud is provided by the embodiments of the present disclosure. The cloud includes a memory, a processor, and a computer program stored in the memory and executable on the processor. The processor executes the computer program to implement the method for controlling rollover prevention of the tank truck according to above embodiments.

In a sixth aspect, a tank truck is provided by the embodiments of the present disclosure. The tank truck includes a memory, a processor, and a computer program stored in the memory and executable on the processor. The processor executes the computer program to implement the method for controlling rollover prevention of the tank truck according to above embodiments.

In a seventh aspect, a system for controlling rollover prevention of a tank truck is provided by the embodiments of the present disclosure. The system includes: a tank truck including a sensor, a communication device, and a vehicle calculation unit, where the communication device communicates with a cloud, and the vehicle calculation unit, internally including an observation and state estimator and a controller, obtains state variables related to a vehicle and liquid by using sensor data and a surrogate model, and controls the rollover prevention of the tank truck by using the surrogate model; and a cloud including a cloud information space and providing a parameter calibration service for the surrogate model by using a vehicle fine model and a liquid sloshing fine model that are digital twins of the surrogate model.

In an eighth aspect, a computer-readable storage medium is provided according to embodiments of the present disclosure. The computer-readable storage medium stores a computer program. The computer program is executed by a processor to implement the method for controlling rollover prevention of the tank truck according to the above embodiments.

Accordingly, the present disclosure has at least the following beneficial effects. According to the embodiments of the present disclosure, characteristics of high computation power of a cloud and high real-time performance of a vehicle (a tank truck) side can be utilized to establish a more accurate model. Data obtained by the vehicle side in real time is transmitted to the cloud. More accurate model calibration parameter results are calculated by the cloud as desired and transmitted to the vehicle side to realize model predictive control. Based on vehicle-cloud collaborative control architecture, the vehicle-cloud collaborative control architecture of cloud finite element calibration plus vehicle-side real-time control is developed to prevent the tank truck from entering a dangerous state, which realizes prediction of danger in advance, ensuring beneficial effects such as driving safety. In this way, technical problems in the related art such as an inability to realize rollover prevention of the tank truck through real-time calculation and an inability to support a huge calculation amount are solved.

Additional aspects and advantages of the present disclosure will be provided at least in part in the following description, or will become apparent at least in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a flowchart of a method for controlling rollover prevention of a tank truck according to an embodiment of the present disclosure.

FIG. 2 is a schematic diagram of a TruckSim vehicle fine dynamics model according to an embodiment of the present disclosure.

FIG. 3 is a schematic diagram of a StarCCM+ fine liquid sloshing finite element model according to an embodiment of the present disclosure.

FIG. 4 is a flowchart of a method for modeling liquid sloshing in a tank of a tank truck according to an embodiment of the present disclosure.

FIG. 5 is a schematic diagram of a single-degree-of-freedom multi-mass elliptical pendulum according to an embodiment of the present disclosure.

FIG. 6 is a schematic diagram of a multi-degree-of-freedom multi-mass elliptical pendulum according to an embodiment of the present disclosure.

FIG. 7 is a schematic diagram of a linear combination of a simple pendulum and/or an elliptical pendulum according to an embodiment of the present disclosure.

FIG. 8 is a schematic diagram of a nonlinear combination of a simple pendulum and/or an elliptical pendulum according to an embodiment of the present disclosure.

FIG. 9 is a schematic diagram of a simple pendulum model according to an embodiment of the present disclosure.

FIG. 10 is a schematic diagram of an elliptical pendulum model according to an embodiment of the present disclosure.

FIG. 11 is a schematic structural and dynamics diagram of a double mass trammel pendulum according to an embodiment of the present disclosure.

FIG. 12 is a schematic structural and dynamics diagram of a combined double pendulum according to an embodiment of the present disclosure.

FIG. 13 is a flowchart of a method for controlling rollover prevention of a tank truck according to another embodiment of the present disclosure.

FIG. 14 is a schematic diagram of a double mass trammel pendulum DMTP model according to an embodiment of the present disclosure.

FIG. 15 is a flowchart of a method for estimating a state variable of liquid sloshing based on a liquid level fluctuation sensor according to an embodiment of the present disclosure.

FIG. 16 is a schematic diagram of a six-degree-of-freedom simplified semi-trailer tank truck model according to an embodiment of the present disclosure.

FIG. 17 is a schematic diagram of a control algorithm for trajectory tracking plus sway suppression plus rollover prevention according to an embodiment of the present disclosure.

FIG. 18 is a schematic diagram of illustrating use of a specific model according to a specific embodiment of the present disclosure.

FIG. 19 is a schematic diagram of a method for controlling rollover prevention of a tank truck according to a specific embodiment of the present disclosure.

FIG. 20 is a flowchart of a method for controlling rollover prevention of a tank truck according to a specific embodiment of the present disclosure.

FIG. 21 is a schematic diagram of an apparatus for controlling rollover prevention of a tank truck according to an embodiment of the present disclosure.

FIG. 22 is a schematic diagram of an apparatus for controlling rollover prevention of a tank truck according to another embodiment of the present disclosure.

FIG. 23 is a schematic diagram of a system for controlling rollover prevention of a tank truck according to an embodiment of the present disclosure.

FIG. 24 is an architecture diagram of a system for controlling rollover prevention of a tank truck according to an embodiment of the present disclosure.

### DETAILED DESCRIPTION OF THE EMBODIMENTS

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limit, the present disclosure.

A method and apparatus for controlling rollover prevention of a tank truck, a cloud, a tank truck, and a system for controlling rollover prevention of a tank truck according to the embodiments of the present disclosure are described below with reference to the accompanying drawings. To address the problems mentioned in the background such as the inability to realize real-time calculation due to an extremely large amount of calculation of a finite element model, the inability to support the huge amount of calculation in a liquid surrogate model by a computation power of the vehicle side, the present disclosure provides the method for controlling rollover prevention of the tank truck. With this method, characteristics of a large computation power of the cloud and high real-time performance of the vehicle side are utilized. A vehicle-cloud collaborative control architecture of cloud finite element calibration plus vehicle-side real-time control is developed. Accurate model parameter calibration results are obtained by cloud computing to realize model predictive control. In this way, problems in the related art such as an inability to realize rollover prevention of the tank truck through real-time calculation and an inability to support a huge calculation amount are solved.

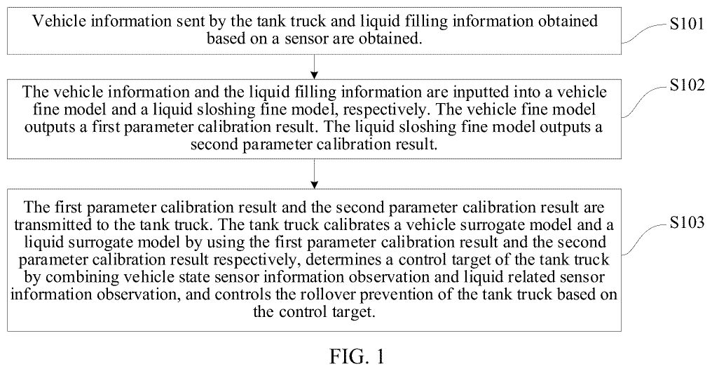

In an exemplary embodiment of the present disclosure, FIG. 1 is a schematic flowchart of a method for controlling rollover prevention of a tank truck according to an embodiment of the present disclosure.

As illustrated in FIG. 1, the method for controlling rollover prevention of the tank truck is applied to a cloud and includes the following operations.

At block S101, vehicle information sent by the tank truck and liquid filling information obtained based on a sensor are obtained.

At block S102, the vehicle information and the liquid filling information are inputted into a vehicle fine model and a liquid sloshing fine model, respectively. The vehicle fine model outputs a first parameter calibration result. The liquid sloshing fine model outputs a second parameter calibration result.

The vehicle fine model is a multi-body dynamics model, and may use a semi-trailer tank truck model (no-load model without liquid) established by TruckSim. The liquid sloshing fine model is a finite element model, which may be established by using StarCCM+software. A specific model establishment process is described as follows.

It should be understood that, according to the embodiment of the present disclosure, the vehicle information sent by the tank truck may be inputted to the vehicle fine model for parameter calibration and the liquid filling information obtained based on the sensor sent by the tank truck may be inputted to the liquid sloshing fine model for parameter calibration, to obtain the first parameter calibration result and the second parameter calibration result, respectively. Make full use of an advantage of a large computation power of the cloud, remote computing is used to obtain more accurate model parameters.

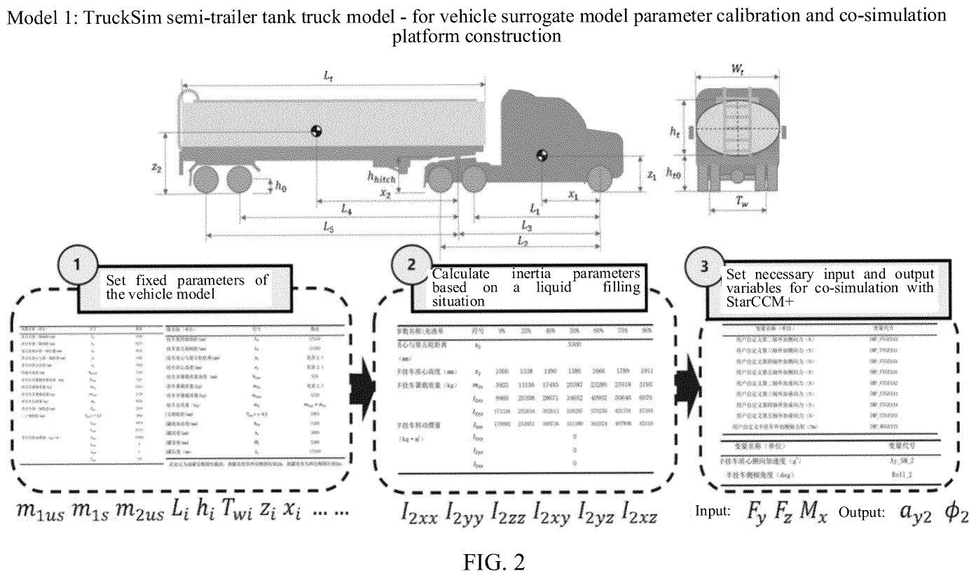

A TruckSim vehicle fine dynamics model is illustrated in FIG. 2. Establishment of an accurate vehicle model in TruckSim is divided into the following steps.

Fixed parameters of the model are set based on vehicle experiment and measurement data. Inertia parameters of a trailer are calculated based on a current liquid filling situation. To build a vehicle-liquid coupling co-simulation platform and realize co-simulation between TruckSim and StarCCM+ software, an input parameter and an output parameter of the model also need to be set. Input variables mainly include a lateral force and a vertical force exerted on an axle by the outside world and a roll torque exerted on a sprung mass of the trailer by the outside world. These forces come from output of a finite element liquid model. Output variables at least include a lateral acceleration and a roll angle of the trailer, and are used to calculate acceleration components exerted on the finite element model.

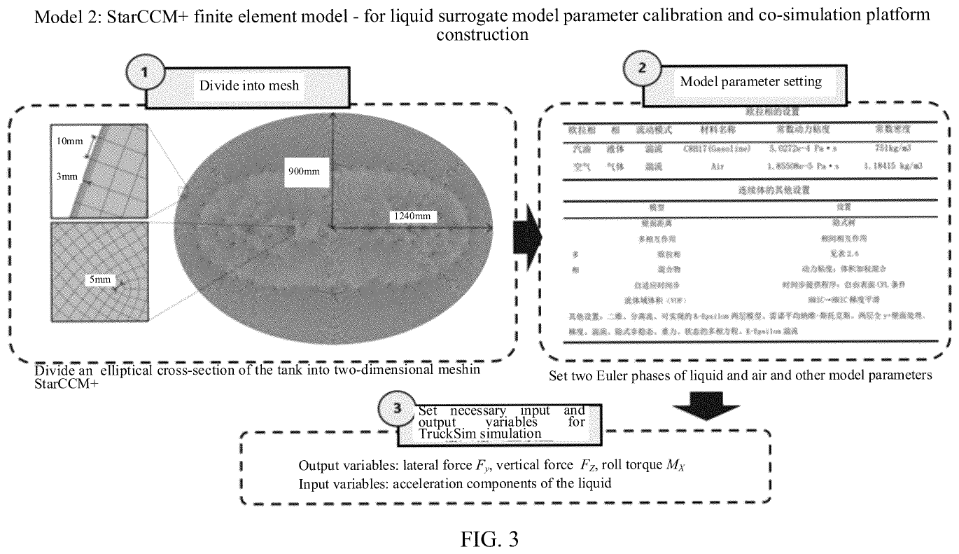

A StarCCM+ liquid sloshing finite element model is illustrated in FIG. 3. Establishment of the StarCCM+ finite element model for liquid sloshing in the tank is divided into the following steps.

A cross-section of the tank is divided into two-dimensional mesh with certain accuracy to ensure that details of the liquid sloshing may be captured. A cloud platform may also be extended to a three-dimensional finite element model. Two Euler phases of liquid and air and their physical properties are set, and other parameters of the model are set. An input variable and an output variable of the co-simulation with TruckSim are set in the form of reports and drawings. A lateral force, a vertical force, and a roll torque are outputted by the finite element model to the vehicle model, and an influence of the vehicle on the liquid is reflected by continuously updating acceleration components of the liquid in the simulation. At block S103, the first parameter calibration result and the second parameter

calibration result are transmitted to the tank truck. The tank truck calibrates a vehicle surrogate model and a liquid surrogate model by using the first parameter calibration result and the second parameter calibration result respectively, determines a control target of the tank truck by combining vehicle state sensor information observation and liquid related sensor information observation, and controls the rollover prevention of the tank truck based on the control target.

The vehicle surrogate model is a linear simplified dynamics model. The liquid surrogate model is an equivalent pendulum dynamics model. Vehicle state sensors include GPS, IMU, a wheel speed sensor, and the like. The liquid-related sensor may be a free liquid level fluctuation sensor, which can ensure real-time measurement of an average inclination angle of a liquid surface and a liquid level under a static state. The control target is trajectory tracking plus sway suppression plus rollover prevention.

It should be understood that, according to the embodiment of the present disclosure, the first parameter calibration result and the second parameter calibration result are transmitted by the cloud to the tank truck. The tank truck calibrates the vehicle surrogate model by using the first parameter calibration result, and calibrates the liquid surrogate model by using the second parameter calibration result. The control target of the tank truck is determined by combining the vehicle state sensor information observation and the liquid related sensor information observation, and the rollover prevention of the tank truck is controlled based on the control target. In this way, advance prediction of a liquid dynamic state of the tank truck is realized, which prevents the vehicle from entering a dangerous state.

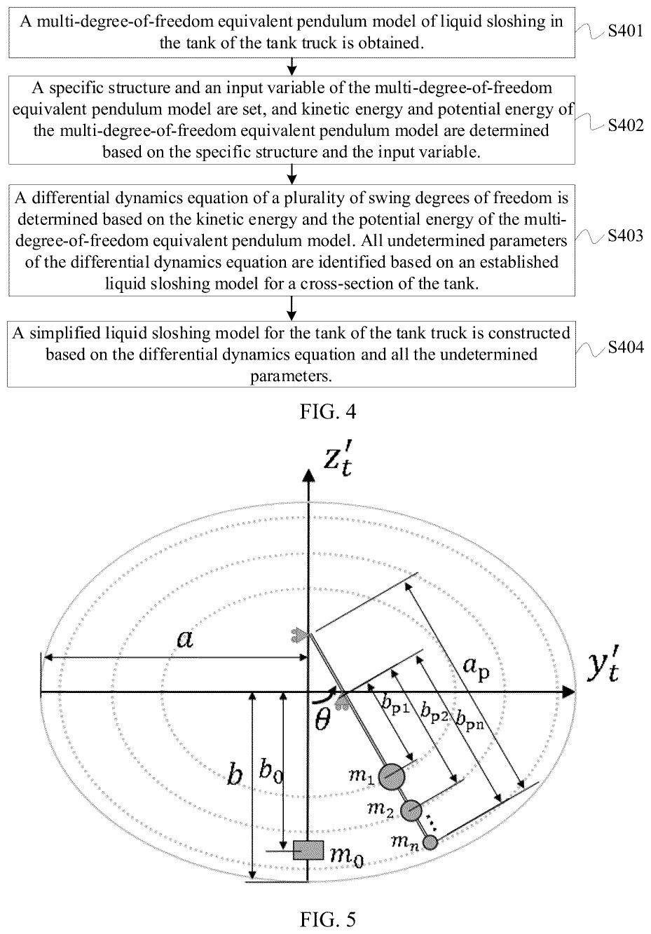

A method for modeling liquid sloshing in a tank of a tank truck according to an embodiment of the present disclosure is described below in conjunction with FIG. 4.

As illustrated in FIG. 4, the method for modeling liquid sloshing in the tank of the tank truck includes the following operations.

At block S401, a multi-degree-of-freedom equivalent pendulum model of liquid sloshing in the tank of the tank truck is obtained.

In an embodiment of the present disclosure, obtaining the multi-degree-of-freedom equivalent pendulum model of liquid sloshing in the tank of the tank truck includes: taking a pendulum rod and a lumped mass as basic units; hinging an end of the pendulum rod to a point or a lumped mass in the cross-section of the tank; determining a motion track of the lumped mass connected by the pendulum rod without a fixing end as a part of an ellipse; and allowing the lumped mass to hinge a plurality of pendulum rods, and allowing one or more lumped masses to be fixed to a point in the cross-section of the tank with the one or more lumped masses not connecting any pendulum rod to establish the multi-degree-of-freedom equivalent pendulum model.

In the embodiment of the present disclosure, the multi-degree-of-freedom equivalent pendulum model is a system that contains nₘ lumped masses and nₓ specific input variables and satisfies specific connection rules. The rules include the following aspects.
Rule 1, the pendulum rod and the lumped mass are taken as basic units.
Rule 2, an end of the pendulum rod is hinged to and fixed at a certain point in the cross-section of the tank, or not fixed, or connected to one lumped mass.
Rule 3, when the pendulum rod has no fixing end, the motion track of the lumped mass connected by the pendulum rod needs to be a part of the ellipse.
Rule 4, the lumped mass may hinge the plurality of pendulum rods.
Rule 5, n_{fm} lumped masses are allowed to be fixed to a certain point in the cross-section of the tank with the n_{fm} lumped masses not connecting any pendulum rod, where n_{fm}≤nₘ−2.

Further, when the above system that contains the nₘ lumped masses and the nₓ specific input variables and satisfies specific connection rules is called a “multi-degree-of-freedom pendulum model”, nₘ+nₓ−n_{fm} generalized coordinates and nₘ−n_{fm} degrees of freedom are included.

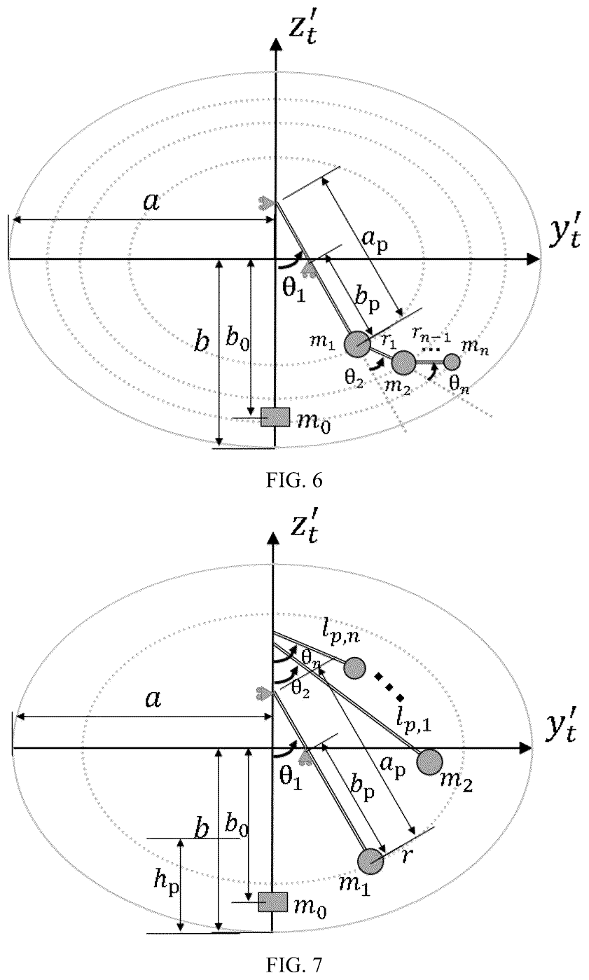

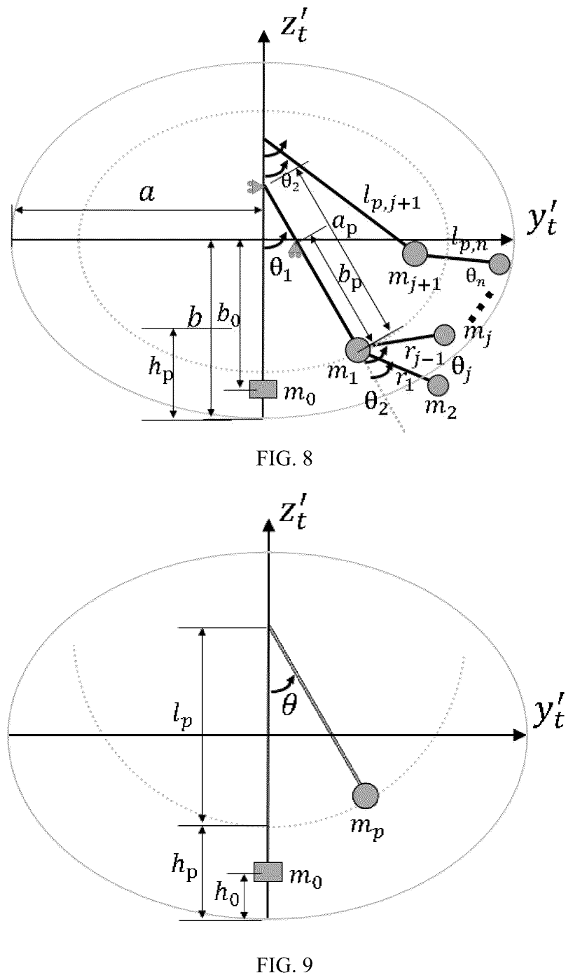

To facilitate understanding, in the embodiment of the present disclosure, FIG. 5 illustrates a multi-mass elliptical pendulum with a single degree of freedom. In conjunction with the above rules, the model illustrated in FIG. 5 does not conform to a specific connection mode in a specific structure of the above model according to the embodiment of the present disclosure, because a plurality of lumped masses are connected to one pendulum rod, which violates the above rule 2. As illustrated in FIG. 6, FIG. 7, and FIG. 8, cases consistent with the embodiments of the present disclosure are illustrated, respectively. FIG. 8 illustrates a multi-degree-of-freedom multi-mass trammel pendulum.

It should be noted that, the embodiments of the present disclosure are not limited to a specific shape of the cross-section of the tank, and are applicable to most convex cross-sectional shapes without longitudinal baffles.

At block S402, a specific structure and an input variable of the multi-degree-of-freedom equivalent pendulum model are set, and kinetic energy and potential energy of the multi-degree-of-freedom equivalent pendulum model are determined based on the specific structure and the input variable.

It should be understood that, according to the embodiments of the present disclosure, a specific structure of a simplified liquid sloshing model may be specified. The specific structure includes ma lumped masses (nₘ≥2) and their specific connection modes, and nₓ specific input variables.

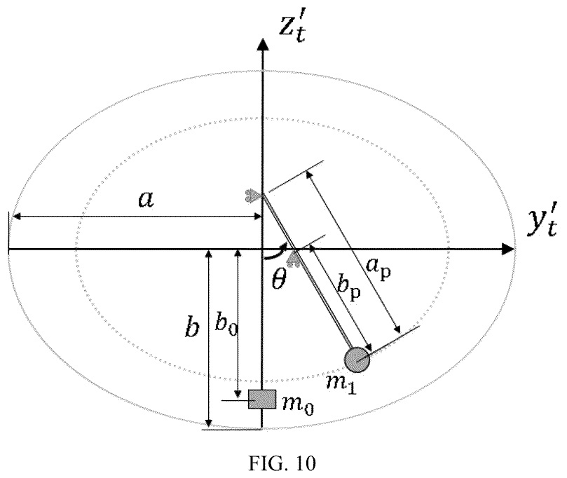

The specific structure may include a linear and/or non-linear combination of at least a plurality of simple pendulums and/or elliptical pendulums. A schematic diagram of a simple pendulum is illustrated in FIG. 9, and a schematic diagram of an elliptical pendulum is illustrated in FIG. 10. A linear combination (in parallel) of at least two simple pendulums and/or elliptical pendulums is illustrated in FIG. 6. A nonlinear combination (in series) of at least two simple pendulums and/or elliptical pendulums is illustrated in FIG. 7.

In an embodiment of the present disclosure, determining the kinetic energy and potential energy of the multi-degree-of-freedom equivalent pendulum model based on the specific structure and the input variable includes: setting an acting point and a positive direction of an output force and a torque of the multi-degree-of-freedom equivalent pendulum model in the cross-section of the tank, and establishing a plane rectangular coordinate system by taking the acting point as an origin and taking the positive direction as a coordinate axis; expressing a position vector of each lumped mass of the multi-degree-of-freedom equivalent pendulum model in the plane rectangular coordinate system, and calculating a first derivative and a second derivative of the position vector of each lumped mass with respect to time to obtain a velocity vector and an acceleration vector of each lumped mass; and determining the kinetic energy of the multi-degree-of-freedom equivalent pendulum model and potential energy of the kinetic energy of the multi-degree-of-freedom equivalent pendulum model at a designated zero potential energy point by using the position vector, the velocity vector, and the acceleration vector.

In the embodiment of the present disclosure, the kinetic energy and the potential energy of the multi-degree-of-freedom equivalent pendulum model are determined based on the specific structure and the input variable, which may be described in detail in conjunction with the following steps.

In step 1, the acting point (which is a bottom of the tank) and the positive direction (right and upper, clockwise) of the output force and the torque of a liquid sloshing system in the cross-section of the tank are specified, and the plane rectangular coordinate system is established in the cross-section of the tank by taking the bottom of the tank as the origin and taking the right and upper positive directions as coordinate axes.

In step 2, the position vector of each lumped mass of the multi-degree-of-freedom equivalent pendulum model is expressed in the plane rectangular coordinate system in the step 1:

$$\vec{R \text{?}} = {p}_{o y} \vec{J} + {p}_{0 z} \vec{k} i = 1 , 2 , … , {n}_{m} \qquad ( 1 )$$

$$\text{?} \text{indicates text missing or illegible when filed}$$

In step 3, the first derivative and the second derivative of the position vector of each lumped mass with respect to time in step 2 are calculated to obtain the velocity vector and the acceleration vector of each lumped mass:

$$\begin{matrix}\dot{\vec{{R}_{pt}}} = \frac{d}{dt} \vec{{R}_{p ι}} = {v}_{1 y} \vec{J} + {v}_{1 z} \vec{k} , & i = 1 , 2 , … , {n}_{m}\end{matrix} \qquad ( 2 )$$

$$\begin{matrix}{\vec{{R}_{pt}}}^{\cdot \cdot } = \frac{{d}^{2}}{{dt}^{2}} \vec{{R}_{p ι}} = {a}_{1 y} \vec{J} + {a}_{1 z} \vec{k} , & i = 1 , 2 , … , {n}_{m}\end{matrix} \qquad ( 3 )$$

In step 4, a kinetic energy T of the system and the potential energy U of the system at the designated zero potential energy point are expressed by using the position vector in the step 2 and the velocity vector, the acceleration vector in the step 3:

$$\begin{matrix}T = {\sum }_{i = 0}^{2} \frac{1}{2} {m}_{i} ( {v}_{iy}^{2} + {v}_{iz}^{2} ) , & i = 1 , 2 , … , {n}_{m}\end{matrix} \qquad ( 4 )$$

When a x₂^{B}o₂^{B}y₂^{B} plane is a zero potential energy surface, a potential energy expression of the system is:

$$\begin{matrix}U = {\sum }_{i = 0}^{2} {m}_{i} {gp}_{iz} , & i = 1 , 2 , … , {n}_{m}\end{matrix} \qquad ( 5 )$$

At block S403, a differential dynamics equation of a plurality of swing degrees of freedom is determined based on the kinetic energy and the potential energy of the multi-degree-of-freedom equivalent pendulum model. All undetermined parameters of the differential dynamics equation are identified based on an established liquid sloshing model for a cross-section of the tank.

It should be understood that, in the embodiment of the present disclosure, differential dynamic equations of all n swing degrees of freedom of the model may be established by a method solving a Lagrange equation of the system, in such a manner that undetermined parameters in the differential equation are calibrated by using finite element simulation data of a modeled system under a specified standard operation condition.

In an embodiment of the present disclosure, identifying all undetermined parameters of the differential dynamics equation based on the established liquid sloshing model for the cross-section of the tank includes: setting a plurality of output variables of the liquid sloshing model and an output mode for the output variables; obtaining output variable time series data of the plurality of output variables based on a predetermined operation condition, and constructing a cost function of an undetermined parameter of the differential dynamics equation based on the output mode for the output variables and the output variable time series data; and optimizing the cost function and identifying all undetermined parameters of the differential dynamics equation based on the optimized cost function.

The output variables include a lateral force, a vertical force, and a roll torque. The predetermined operation condition includes a lateral acceleration step excitation operation condition and/or a lateral acceleration sinusoid fluctuation operation condition, which may also be used under severe input. The cost function is a non-negative weighted sum of all error terms.

In an exemplary embodiment of the present disclosure, by using the kinetic energy T and the potential energy U in the above embodiments, a differential dynamic equation of each degree of freedom of the system is solved based on a Lagrange equation:

$$\begin{matrix}\frac{d}{dt} \frac{\partial T}{\partial \dot{{θ}_{1}}} - \frac{\partial T}{\partial {θ}_{i}} + \frac{\partial U}{\partial {θ}_{i}} = 0 , & i = 1 , 2 , … , {n}_{m} - {n}_{fm} ,\end{matrix} \qquad ( 6 )$$

where t represents time, θᵢ represents the generalized coordinate corresponding to the i-th degrees of freedom.

Preferably, a specific solution result expression is obtained by using a following function of Matlab software:

functionalDerivative(L,[θₗ, . . . ])==[0,0]

By sorting out \ddot{θ}ₗ in the two expressions, a second derivative differential equation of other variables with respect to each of \ddot{θ}ₗ is formed, and damping terms are added at ends.

$${\ddot{θ}}_{ι} = {f}_{i} ( \ddot{y} , \ddot{z} , φ , \dot{φ} , \ddot{φ} , {θ}_{1} , {\dot{θ}}_{1} , {θ}_{2} , {\dot{θ}}_{2} ) - {c}_{1} {\dot{θ}}_{1} \qquad ( 7 )$$

A differential equation set about \ddot{θ}ₗ may be constructed through the above fₗ expression, and a whole dynamic process of the model may be solved by a numerical integration method. The input variables of the above two equations are ÿ, \ddot{z}, \ddot{φ}, and other variables are all used as state variables of the differential equation set. After an initial value is assigned, a result is saved every time calculation is performed. When the next step needs to be calculated, the state variable saved in a previous step is taken out as the initial value.

Further, in the embodiment of the present disclosure, StarCCM+ or ANSYS/Fluent software may be used to establish a two-dimensional finite element liquid sloshing model in the cross-section of the tank. The two-dimensional finite element liquid sloshing model includes two Euler phases, in which medium are air and gasoline, and specifies n_{y}=3 output variables that are a lateral force f_{y}, a vertical force F_{z}, and a roll torque Mₓ, respectively. Preferably, output modes of n_{y} output variables are realized by setting required output reports and creating forms of their drawings. When the simulation is completed, all time series data may be exported through export functions of the drawings.

In an actual implementation process, the embodiment of the present disclosure may specify n_{cd}=5 standard operation conditions that are lateral acceleration step excitation operation conditions of lateral acceleration a_{y}=1,2,3,4,5 m/s² and preferably simulate for 10 s. A total of n_{cd}n_{y}=5×3=15 sets of output variable time series data of n_{y} output variables are obtained based on specified n_{cd} standard operation conditions.

Further, according to the embodiment of the present disclosure, the cost function of the undetermined parameter of the differential dynamics equation may be constructed. The cost function is the non-negative weighted sum of all error terms with same weights, and a specific form is as follows.

To avoid overfitting of parameters, which results in the model only better fitting a system response under a certain acceleration used in parameter identification, an average value of a standard deviation of three-directional forces under a total of five operation conditions a_{y}=1,2,3,4,5 m/s² is selected as a final cost variable to construct the cost function as illustrated in equation (8).

$$J = \text{} mean ( {‖ \frac{{F}_{y , {a}_{y}} - {F}_{y 0 , {a}_{y}}}{\overline{{F}_{y 0 , {a}_{y}}}} ‖}_{2}^{2} + {‖ \frac{{F}_{z , {a}_{y} - {F}_{z 0 , {a}_{y}}}}{\overline{{F}_{z 0 , {a}_{y}}}} ‖}_{2}^{2} + {‖ \frac{{M}_{x , {a}_{y} - {M}_{x 0 , {a}_{y}}}}{\overline{{M}_{x 0 , {a}_{y}}}} ‖}_{2}^{2} ) \cdot {a}_{y} = 1 , 2 , 3 , 4 , 5 \qquad ( 8 )$$

$$That is ,$$

$$J = \frac{1}{5} {\sum }_{{a}_{y} = 1}^{5} {\sum }_{k = 0}^{N} ( {( \frac{{F}_{y , {a}_{y} ( k )} - {F}_{y 0 , {a}_{y}} ( k )}{\overline{{F}_{y 0 , {a}_{y}}}} )}^{2} + {( \frac{{F}_{z , {a}_{y}} ( k ) - {F}_{z 0 , {a}_{y}} ( k )}{\overline{{F}_{z 0 , {a}_{y}}}} )}^{2} + \qquad ( 9 )$$

$${( \frac{{M}_{x , {a}_{y}} ( k ) - {M}_{x 0 , {a}_{y}} ( k )}{\overline{{M}_{x 0 , {a}_{y}}}} )}^{2} )$$

where F̅_̅{̅y̅0̅,̅a̅}̅_̅{̅_̅{̅y̅}̅}̅, F̅_̅{̅z̅0̅.̅a̅}̅_̅{̅_̅{̅y̅}̅}̅, M̅_̅{̅x̅0̅,̅a̅}̅_̅{̅_̅{̅y̅}̅}̅ represent time averages of the three-directional forces of CFD step data, respectively.

$$\{ \begin{matrix}\overline{{F}_{y 0 , {a}_{y}}} = \frac{1}{N + 1} {\sum }_{k = 0}^{N} {F}_{y 0 , {a}_{y}} ( k ) \\ \overline{{F}_{z 0 , {a}_{y}}} = \frac{1}{N + 1} {\sum }_{k = 0}^{N} {F}_{z 0 , {a}_{y}} ( k ) \\ \overline{{M}_{x 0 , {a}_{y}}} = \frac{1}{N + 1} {\sum }_{k = 0}^{N} {M}_{x 0 , {a}_{y}} ( k )\end{matrix} , \qquad ( 10 )$$

F_{y,a}_{_{y}} represents the lateral force F_{y} outputted by the model under step excitation of the lateral acceleration a_{y}, F_{z,a}_{_{y}} represents the vertical force F_{z} outputted by the model under the step excitation of the lateral acceleration a_{y}, M_{x,a}_{_{y}} represents the roll torque Mₓ outputted by the model under the step excitation of the lateral acceleration a_{y}, each of outputs of the above three-directional forces is in a form of time series, k represents an output variable at a k-th time point, with a total of N+1 time points.

Further, in the embodiment of the present disclosure, all undetermined parameters in the differential dynamics equation may be identified by the cost equation optimized by an optimal algorithm. The optimal algorithm may be a genetic algorithm, a particle swarm algorithm, an ant colony algorithm, or a simulated annealing algorithm, and the present disclosure is not limited to any of these examples.

At block S404, a simplified liquid sloshing model for the tank of the tank truck is constructed based on the differential dynamics equation and all the undetermined parameters.

Based on the above embodiments, the simplified liquid sloshing model may be constructed by combining identified undetermined parameters and the differential dynamics equation. When an initial state and initial input are given, a model state at any time point may be solved. Given the state at any time point, outputs of the lateral force, the vertical force and the roll torque at the time point may be calculated.

$$\begin{matrix}{F}_{y} = - {\sum }_{i = 0}^{2} {m}_{i} {a}_{yi} , & i = 0 , 1 , 2\end{matrix} \qquad ( 11 )$$

$$\begin{matrix}{F}_{z} = - {\sum }_{i = 0}^{2} {m}_{i} ( {a}_{zi} + g ) , & i = 0 , 1 , 2\end{matrix} \qquad ( 12 )$$

$$\begin{matrix}{M}_{x} = - {\sum }_{i = 0}^{2} {m}_{i} [ {p}_{zi} {a}_{yt} - {p}_{yi} ( {a}_{zi} + g ) ] , & i = 0 , 1 , 2\end{matrix} \qquad ( 13 )$$

In this way, the kinetic energy and potential energy of the multi-degree-of-freedom equivalent pendulum model are determined by setting the specific structure and input variable of the multi-degree-of-freedom equivalent pendulum model. The differential dynamics equations of the plurality of swing degrees of freedom are determined by the kinetic energy and potential energy of the multi-degree-of-freedom equivalent pendulum model. The undetermined parameters in the differential equation are calibrated by using the finite element simulation data of the modeled system under the specified standard condition, and the simplified liquid sloshing model is constructed based on the identified undetermined parameters and the differential dynamics equation. Compared with an existing single-degree-of-freedom equivalent pendulum model, the multi-degree-of-freedom equivalent pendulum model adopted greatly improves fitting accuracy of a tank dynamics system, has higher universality, is not limited to a specific shape of the cross-section of the tank, and is suitable for most convex cross-section shapes without longitudinal baffles. Also, an accuracy of liquid sloshing modeling is greatly improved while not increasing the calculation amount, which solves problems of small application range of the model and low accuracy of the liquid sloshing modeling in the related art.

The following embodiments of the present disclosure may be combined with a specific embodiment 1 and a specific embodiment 2 to explain steps of the method for modeling liquid sloshing in the tank of the tank truck in detail.

### 1. Specific Embodiment 1

As illustrated in FIG. 8, a liquid sloshing model of a tank with an elliptical cross-section (long axis a=1.24 m, short axis b=0.9 m, a tank length is 11 m, a tank filling rate is 50%) is established by using a 2-degree-of-freedom two-mass trammel pendulum model. Essence of a two-mass trammel pendulum model is a nonlinear combination of a simple pendulum model and an elliptical pendulum model. Only differences from the above-described general embodiments are described below.

In the embodiment of the present disclosure, there are nₘ=3 lumped masses, including one fixed mass and two swing masses. Two swing masses are connected in series, a trajectory of a first swing mass is a part of an ellipse, and specified input variables are a lateral acceleration ÿ, a vertical acceleration \ddot{z}, and a roll angle acceleration \ddot{φ}, i.e. nₓ=3.

In the embodiment of the present disclosure, the position vector in the step 2 is:

$$\vec{{R}_{p0}} = \vec{y} + \vec{z} + \vec{b} - \vec{{b}_{0}} = [ y - ( b - {b}_{0} ) sin φ ] \vec{J} + [ z + ( b - {b}_{0} ) cos φ ] \vec{k} = {p}_{0 y} \vec{J} + {p}_{0 z} \vec{k} \qquad ( 14 )$$

$$\vec{{R}_{p 1}} = \vec{y} + \vec{z} + \vec{b} + \vec{{r}_{1}} = [ y - b sin φ + {a}_{p} sin {θ}_{1} cos φ + {b}_{p} cos {θ}_{1} sin φ ] \vec{J} + [ \text{} z + b cos φ + {a}_{p} sin {θ}_{1} sin φ + {b}_{p} cos {θ}_{1} cos φ ] \vec{k} = {p}_{1 y} \vec{J} + {p}_{1 z} \vec{k} \qquad ( 15 )$$

$$\vec{{R}_{p 2}} = \vec{y} + \vec{z} + \vec{b} + \vec{{r}_{1}} + \vec{{r}_{2}} = [ y - b sin φ + {a}_{p} sin {θ}_{1} cos φ + {b}_{p} cos {θ}_{1} sin φ + r sin ( φ + {θ}_{1} + {θ}_{2} ) ] \vec{J} + [ z + b cos φ + {a}_{p} sin {θ}_{1} sin φ + {b}_{p} cos {θ}_{1} cos φ - r cos ( φ + {θ}_{1} + {θ}_{2} ) ] \vec{k} = {p}_{2 y} \vec{J} + {p}_{2 z} \vec{k} \qquad ( 16 )$$

In the embodiment of the present disclosure, the velocity vector [symbol] and the acceleration vector [symbol] in the step 3 are:

$$\begin{matrix}\dot{\vec{{R}_{p i}}} = \frac{d}{dt} \vec{{R}_{p i}} = {v}_{1 y} \vec{J} + {v}_{1 z} \vec{k} , & i = 0 , 1 , 2\end{matrix} \qquad ( 17 )$$

$$\begin{matrix}{\vec{{R}_{pι}}}^{\cdot \cdot } = \frac{{d}^{2}}{{dt}^{2}} \vec{{R}_{p ι}} = {a}_{1 y} \vec{J} + {a}_{1 z} \vec{k} , & i = 0 , 1 , 2\end{matrix} \qquad ( 18 )$$

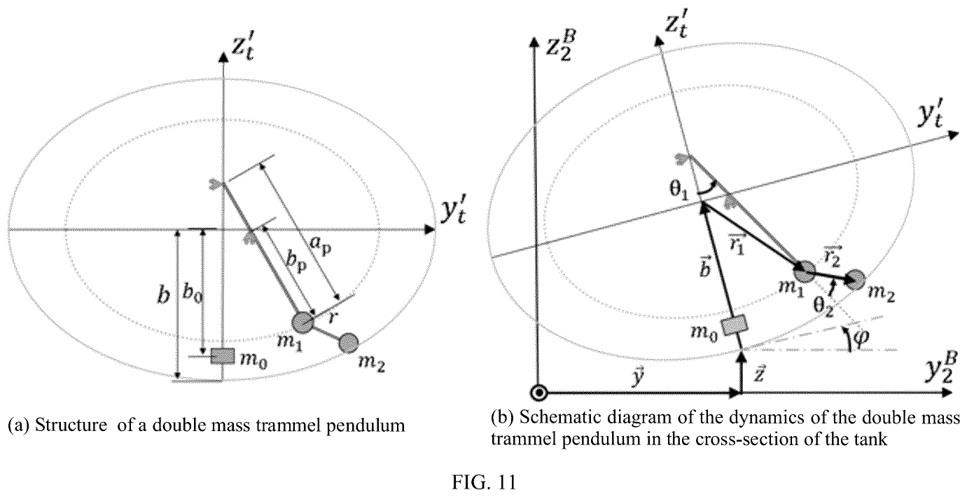

In the embodiment of the present disclosure, please refer to Table 1 for identified undetermined coefficients of the dynamics equation. Table 1 is an independent parameter table of a dual mass trammel pendulum model. For parameters not illustrated in Table 1, please refer to a schematic structural and dynamics diagram of a dual mass trammel pendulum illustrated in FIG. 11.

TABLE 1

| | | | | Identification | |
|---|---|---|---|---|---|
| | | | | result of | |
| | Name of | Physical significance of | Inter-parametric | 50% liquid | |
| Model name | parameter | parameters | constraint | filling rate | |
| DMTP | m₁ | Sloshing mass 1 | m₀ + m₁ + m₂ = m | 841 | kg |
| Number of | m₂ | Sloshing mass 2 | m₀ + m₁ + m₂ = m | 369 | kg |
| independent | s_{ab} | Pendulum length factor | aₚ = s_{ab}a, bₚ = s_{ab}b | −0.307 | |
| parameters: | s₀ | m₀ height factor | b₀ = s₀b | 0.448 | |
| 7 | r | Second-order | | 0.579 | m |
| | | pendulum length | | | |

| | | |
|---|---|---|
| c1 | θ₁ swing damping | 0.0586 |

coefficient

| | | |
|---|---|---|
| c2 | θ₂ swing damping | 1.1272 |

coefficient

### 2. Specific Embodiment 2

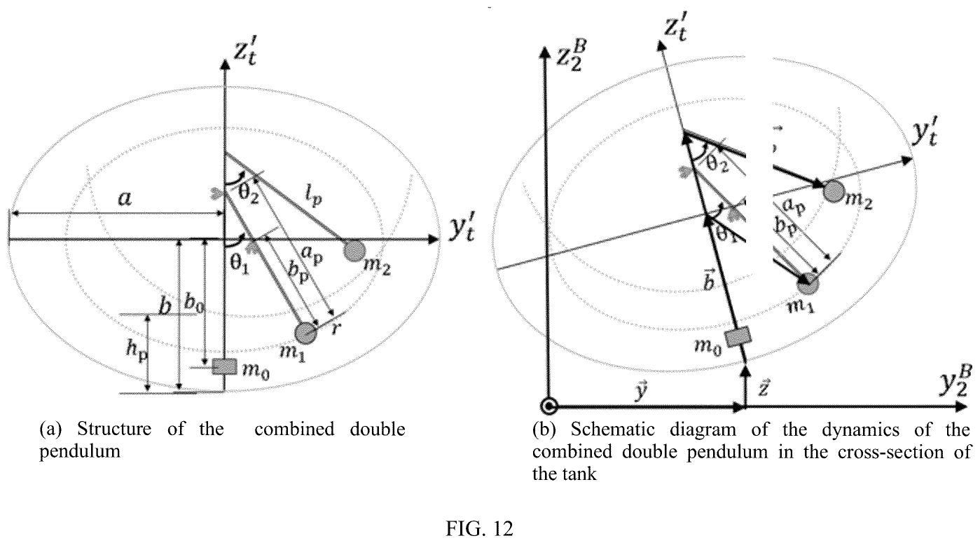

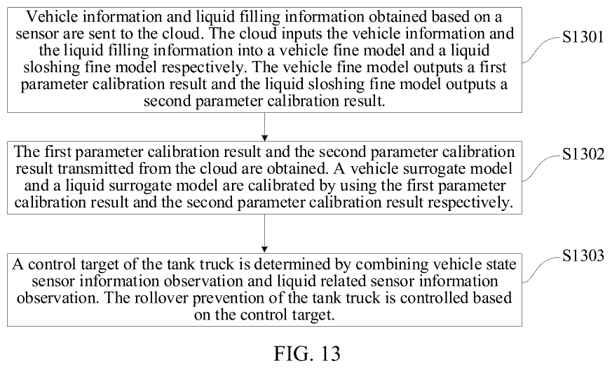

As illustrated in FIG. 12, a liquid sloshing model of a tank with an elliptical cross-section (long axis a=1.24 m, short axis b=0.9 m, a tank length is 11 m, a tank filling rate is 50%) is established by using a 2-degree-of-freedom combined double-pendulum model. Essence of a combined double-pendulum model is a linear combination of a simple pendulum model and a trammel pendulum model. Only differences from the above-described specific embodiments are described below.

In the embodiment of the present disclosure, there are nₘ=3, lumped masses, including one fixed mass and two swing masses. Two swing masses are connected in series, a trajectory of a first swing mass is a part of an ellipse, and specified input variables are a lateral acceleration ÿ, a vertical acceleration \ddot{z}, and a roll angle acceleration \ddot{φ}, i.e. nₓ=3.

In the embodiment of the present disclosure, the position vector in the step 2 is:

$$\vec{{R}_{p0}} = \vec{y} + \vec{z} + \vec{b} - \vec{{b}_{0}} = [ y - ( b - {b}_{0} ) sin φ ] \vec{J} + [ z + ( b - {b}_{0} ) cos φ ] \vec{k} = {p}_{0 y} \vec{J} + {p}_{0 z} \vec{k} \qquad ( 19 )$$

$$\vec{{R}_{p 1}} = \vec{y} + \vec{z} + \vec{b} - \vec{r} = [ y - b sin φ + {a}_{p} sin {θ}_{1} cos φ + {b}_{p} cos {θ}_{1} sin φ ] \vec{J} + [ \text{} z + b cos φ + {a}_{p} sin {θ}_{1} sin φ + {b}_{p} cos {θ}_{1} cos φ ] \vec{k} = {p}_{1 y} \vec{J} + {p}_{1 z} \vec{k} \qquad ( 20 )$$

$$\vec{{R}_{p 2}} = \vec{y} + \vec{z} + \vec{L} + \vec{{l}_{p}} = [ y - ( {h}_{p} + {l}_{p} ) sin φ + {l}_{p} sin ( φ + {θ}_{2} ) ] \vec{J} + [ \text{} z + ( {h}_{p} + {l}_{p} ) cos φ - {l}_{p} cos ( φ + {θ}_{2} ) \vec{k} = {p}_{2 y} \vec{J} + {p}_{2 z} \vec{k} \qquad ( 21 )$$

In the embodiment of the present disclosure, the velocity vector [symbol] and the acceleration vector [symbol] in the step 3 are:

$$\begin{matrix}\dot{\vec{{R}_{p i}}} = \frac{d}{dt} \vec{{R}_{p i}} = {v}_{1 y} \vec{J} + {v}_{1 z} \vec{k} , & i = 0 , 1 , 2\end{matrix} \qquad ( 22 )$$

$$\begin{matrix}{\vec{{R}_{p ι}}}^{\cdot \cdot } = \frac{{d}^{2}}{{dt}^{2}} \vec{{R}_{p ι}} = {a}_{1 y} \vec{J} + {a}_{1 z} \vec{k} , & i = 0 , 1 , 2\end{matrix} \qquad ( 23 )$$

In the embodiment of the present disclosure, please refer to Table 2 for identified undetermined coefficients of the dynamics equation. Table 2 is an independent parameter table of the combined double-pendulum trammel pendulum model. For parameters not illustrated in Table 2, please refer to a schematic structural and dynamics diagram of a combined double-pendulum illustrated in FIG. 12.

TABLE 2

| | | | | Identification | |
|---|---|---|---|---|---|
| | | | | result of | |
| Model | Name of | Physical significance of | Inter-parametric | 50% liquid | |
| name | parameter | parameters | constraint | filling rate | |
| TPSP | m₁ | Sloshing mass 1 | m₀ + m₁ + m₂ = m | 456 | kg |
| Number of | m₂ | Sloshing mass 2 | m₀ + m₁ + m₂ = m | 590 | kg |
| independent | h₀ | m₀ height relative to a | | 1.156 | m |
| parameters: | | bottom of the tank | | | |
| 8 | s_{ab} | Pendulum length factor | aₚ = s_{ab}a | 0.648 | |
| | | | bₚ = s_{ab}b | | |
| | hₚ | mₚ minimum height | | 0.181 | m |
| | | relative to a bottom of | | | |
| | | the tank | | | |
| | lₚ | Length of equivalent | | 0.9849 | m |
| | | pendulum | | | |

| | | |
|---|---|---|
| c1 | θ₁ swing damping | 0.0512 |

coefficient

| | | |
|---|---|---|
| c2 | θ₂ swing damping | 0.0769 |

coefficient

With the method for controlling rollover prevention of the tank truck according to the embodiment of the present disclosure, a calculation advantage of a high computation power of the cloud may be utilized to obtain a more accurate model parameter calibration result. The model parameter calibration result is transmitted to the vehicle (the tank truck) side for realizing model predictive control, which can predict the dynamics of the vehicle and the liquid in advance, preventing the vehicle from entering a dangerous state.

The method for controlling rollover prevention of the tank truck described in the above embodiment is applied to the cloud. The method for controlling rollover prevention of the tank truck described in the following embodiment is applied to the tank truck.

FIG. 13 is a schematic flowchart of a method for controlling rollover prevention of a tank truck according to an embodiment of the present disclosure.

As illustrated in FIG. 13, the method for controlling rollover prevention of the tank truck is applied to the tank truck and includes the following operations.

At block S1301, vehicle information and liquid filling information obtained based on a sensor are sent to the cloud. The cloud inputs the vehicle information and the liquid filling information into a vehicle fine model and a liquid sloshing fine model respectively. The vehicle fine model outputs a first parameter calibration result and the liquid sloshing fine model outputs a second parameter calibration result.

It should be understood that, according to the embodiment of the present disclosure, the tank truck may send the vehicle information and the liquid filling information obtained based on the sensor to the cloud in real time. Through making full use of an advantage of high real-time performance of the vehicle side, parameter calibration calculation is further performed on the vehicle information and the liquid filling information by the cloud.

The cloud inputs the vehicle information and the liquid filling information into the vehicle fine model and the liquid sloshing fine model respectively for calibration, to obtain the first parameter calibration result and the second parameter calibration result.

At block S1302, the first parameter calibration result and the second parameter calibration result transmitted from the cloud are obtained. A vehicle surrogate model and a liquid surrogate model are calibrated by using the first parameter calibration result and the second parameter calibration result respectively.

It should be understood that, according to the embodiment of the present disclosure, the tank truck may obtain the first parameter calibration result and the second parameter calibration result transmitted from the cloud, calibrate the vehicle surrogate model by using the first parameter calibration result, and calibrate the liquid surrogate model by using the second parameter calibration result.

At block S1303, a control target of the tank truck is determined by combining vehicle state sensor information observation and liquid related sensor information observation. The rollover prevention of the tank truck is controlled based on the control target.

It should be understood that, according to the embodiment of the present disclosure, the control target of the tank truck is determined based on the vehicle state sensor information observation. Further, the rollover prevention of the tank truck is controlled based on the control target, which realizes advance prediction of the liquid dynamic state of the tank truck, preventing the vehicle from entering a dangerous state.

It should be noted that, according to the embodiment of the present disclosure, a tank truck side may control the rollover prevention of the tank truck based on the control target through a controller. The controller may be a multi-constraint MPC controller. In the embodiment of the present disclosure, a Double Mass Trammel Pendulum (DMTP) model may be used as a more accurate nonlinear liquid sloshing surrogate model to construct a motion equation in an observer.

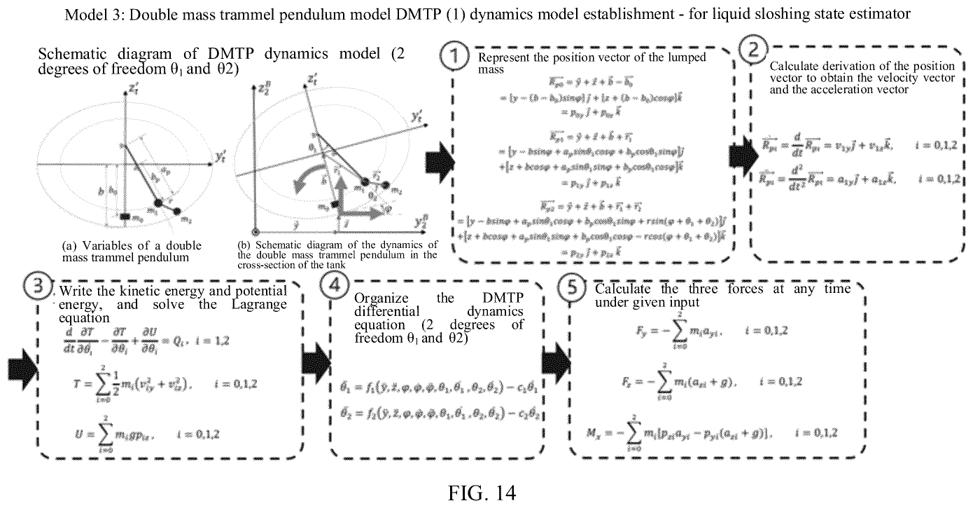

The DMTP model with two degrees of freedom is illustrated in FIG. 14. The DMTP model consists of three lumped masses, including two swing masses and one fixed mass, which may be excited by a lateral acceleration, a vertical acceleration and a roll angle acceleration from a vehicle model. A Lagrange method is used in a derivation process. After expressing position, velocity and acceleration vectors of the three lumped masses, the Lagrange equation may be solved to obtain a differential dynamics equation of two swing degrees of freedom, and three-directional forces at any time point may be obtained under given inputs. As a more accurate but highly nonlinear model, the DMTP model is not suitable for use in vehicle controllers at this stage, but it may be used to design the motion equation of the observer.

In the embodiment of the present disclosure, determining the control target of the tank truck by combining the vehicle state sensor information observation and the liquid related sensor information observation includes: estimating a first state variable of the vehicle surrogate model based on the vehicle state sensor information observation; estimating a second state variable of the liquid surrogate model based on the liquid related sensor information observation; and determining the control target of the tank truck based on the first state variable and the second state variable.

It should be understood that, according to the embodiment of the present disclosure, based on the calibration result obtained in the above step, the first state variable of the vehicle surrogate model required for control may be estimated based on the vehicle state sensor observation. The second state variable of the liquid surrogate model required for control is estimated based on the liquid related sensor information observation. The control target of the tank truck is determined based on the first state variable and the second state variable.

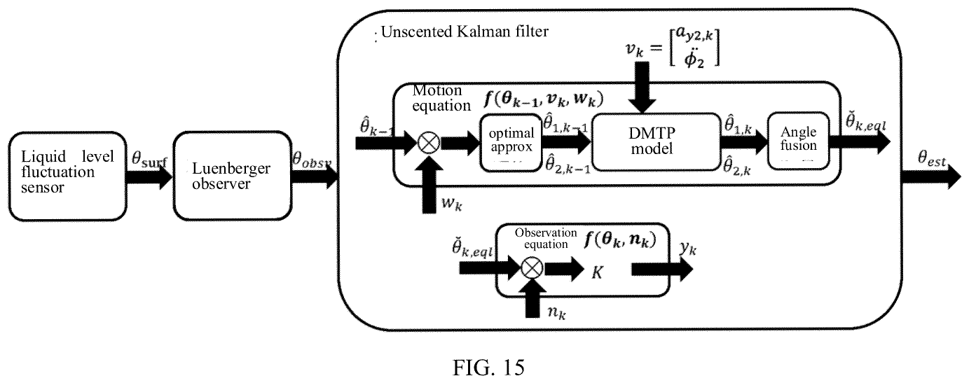

The liquid related sensor may be a free liquid level fluctuation sensor. According to the embodiment of the present disclosure, a liquid sloshing state estimation method using the liquid level fluctuation sensor is illustrated in FIG. 15. A liquid surface average inclination angle data measured by the liquid level fluctuation sensor is smoothed by a Luenberger observer, a smoothed angle is inputted into an unscented Kalman filter that uses a DMTP model to build the motion equation, and finally an estimated equivalent pendulum angle corresponding to the liquid sloshing state is outputted.

It should be noted that, according to the embodiment of the present disclosure, the state variable required for vehicle model control may be estimated by using a 5DOF simplified semi-trailer model. A 6DOF simplified semi-trailer tank truck model may be used as a prediction model used for model predictive control.

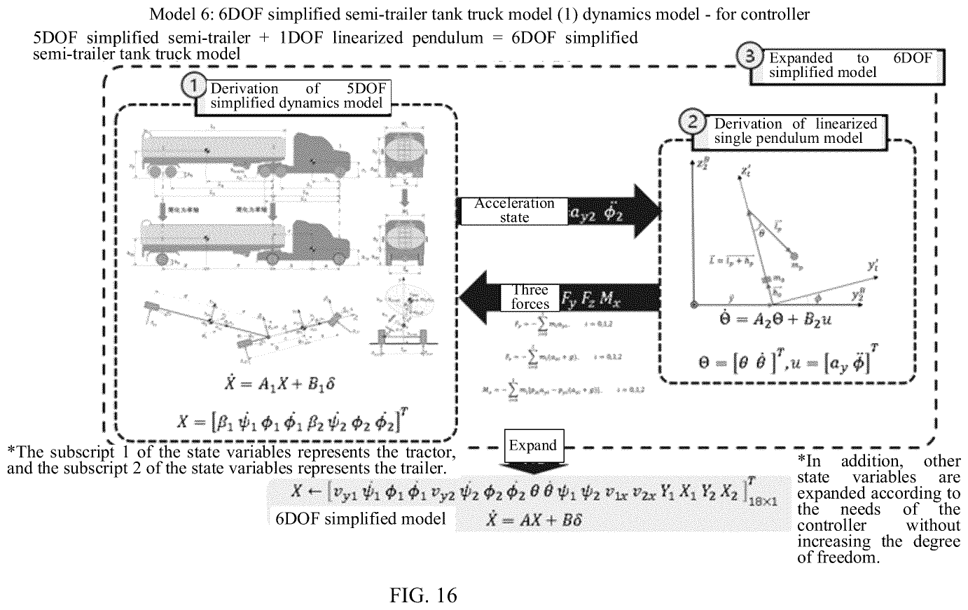

The 6DOF simplified semi-trailer tank truck model used for a model predictive controller in the tank truck side is illustrated in FIG. 16, and is a combination of the 5 DOF semi-trailer model and a linearized single pendulum surrogate model that interact with each other through force and acceleration. After integrating them together and expanding relevant state variables based on requirements of the controller, the 6 DOF semi-trailer tank truck model may be obtained.

In the embodiment of the present disclosure, controlling the rollover prevention of the tank truck based on the control target includes: obtaining a first reference value of the vehicle surrogate model and a second reference value of the liquid surrogate model; determining a first error weight between an output variable of the vehicle surrogate model and the first reference value and a second error weight between an output variable of the liquid surrogate model and the second reference value; and applying the first error weight to the output variable of the vehicle surrogate model to realize a control target of trajectory tracking, applying the second error weight to the output variable of the liquid surrogate model to realize a control target of sway suppression, and performing a soft constraint on a range of a part of output variables of the liquid surrogate model to realize a control target of rollover prevention.

The first reference value and the second reference value may be set according to specific circumstances, and this embodiment is not limited thereto.

It should be understood that, according to the embodiment of the present disclosure, control targets of trajectory tracking and sway suppression are realized by applying error weights corresponding to reference values to output variables of the vehicle surrogate model and the liquid surrogate model, and the control target of rollover prevention is realized by performing the soft constraints on the range of the part of output variables.

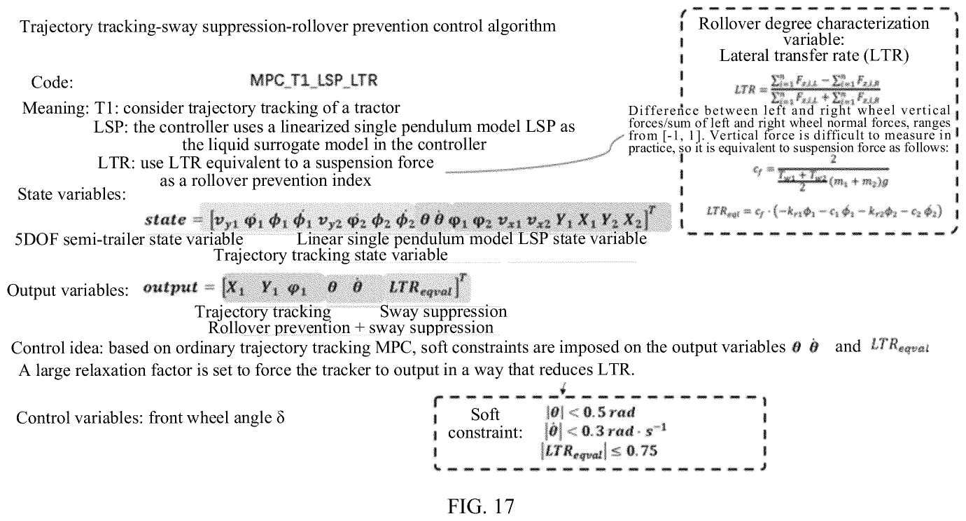

In an exemplary embodiment of the present disclosure, according to the embodiment of the present disclosure, the first error weight between the output variable of the vehicle surrogate model and the first reference value may be determined. The second error weight between the output variable of the liquid surrogate model and the second reference value is determined. The first error weight is applied to the output variable of the vehicle surrogate model to realize the control target of trajectory tracking. The second error weight is applied to the output variable of the liquid surrogate model to realize the control target of sway suppression. The soft constraint is performed on the range of the part of output variables of the liquid surrogate model to realize the control target of rollover prevention. Following formulas are used to achieve the control targets of trajectory tracking plus sway suppression plus rollover prevention. A schematic diagram of the control algorithm for trajectory tracking plus sway suppression plus rollover prevention is illustrated in FIG. 17.

In the embodiment of the present disclosure, the part of output variables to which the soft constraint is applied at least includes Iᵣₒₗₗₒᵥₑᵣ. The output variable of the liquid surrogate model is y=[X₁ Y₁ ψ₁ θ \dot{θ} Iᵣₒₗₗₒᵥₑᵣ], where X represents an x coordinate of a tractor in a world coordinate system, Y represents a y coordinate of the tractor in the world coordinate system, θ represents a swing angle of an equivalent pendulum model, \dot{θ} represents a swing angular velocity of the equivalent pendulum model, Iᵣₒₗₗₒᵥₑᵣ represents a state variable representing a rollover state of a vehicle, ψ₁ represents a heading angle of the tractor.

In the embodiment of the present disclosure, the state variable Iᵣₒₗₗₒᵥₑᵣ representing the rollover state of the vehicle uses a lateral load transfer ratio LTR_{eql} equivalent to a suspension force:

$${LTR}_{eql} = \frac{2}{\frac{{T}_{w 1} + {T}_{w 2}}{2} ( {m}_{1} + {m}_{2} ) g} ( - {k}_{r 1} {ϕ}_{1} - {c}_{1} {\dot{ϕ}}_{1} - {k}_{r 2} {ϕ}_{2} - {c}_{2} {\dot{ϕ}}_{2} ) ,$$

where T_{w} represents an average track length of each axle, m represents a mass of the vehicle, g represents an acceleration of gravity, kᵣ represents roll angle stiffness, c represents roll damping, ϕ represents a roll angle, \dot{ϕ} represents roll angular velocity, a subscript 1 represents the tractor, and a subscript 2 represents a trailer.

It should be noted that, in the above formula of the lateral load transfer ratio, the subscript 1 represents the tractor and the subscript 2 represents the trailer. For an integral tank truck without the trailer, the value of the subscript 1 may be substituted into the subscript 2.

With to the method for controlling rollover prevention of the tank truck according to the embodiment of the present disclosure, by using the advantage of high real-time performance of the vehicle side, the vehicle information and the liquid filling information of the tank truck are sent to the cloud in real time. Further, the model processing data of the cloud is controlled, and the model parameter calibration result transmitted from the cloud is received. By using the model predictive control of the vehicle side, the tank truck and a liquid dynamic state are predicted in advance, which prevents the tank truck from entering a dangerous state.

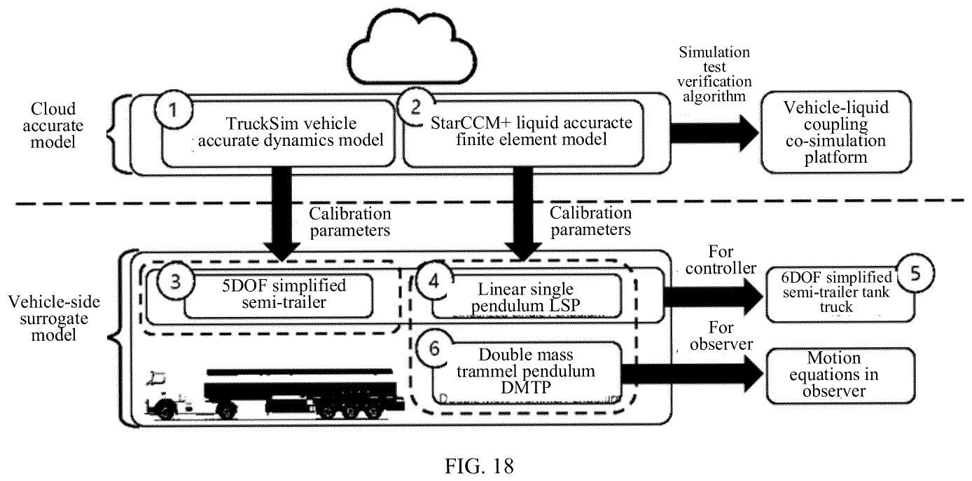

In combination with the methods for controlling rollover prevention of the tank truck applied to the cloud and the tank truck respectively described in the above embodiments, the method for controlling rollover prevention of the tank truck in the present disclosure is described below through a specific embodiment. Specific uses of the models used in the present embodiment are illustrated in FIG. 18, including a cloud accurate model (the TruckSim vehicle fine dynamics model, the StarCCM+ liquid fine finite element model), a vehicle-side surrogate model (a 5DOF simplified semi-trailer, a linear single pendulum LSP, a 6DOF simplified semi-trailer, a double mass trammel pendulum DMTP).

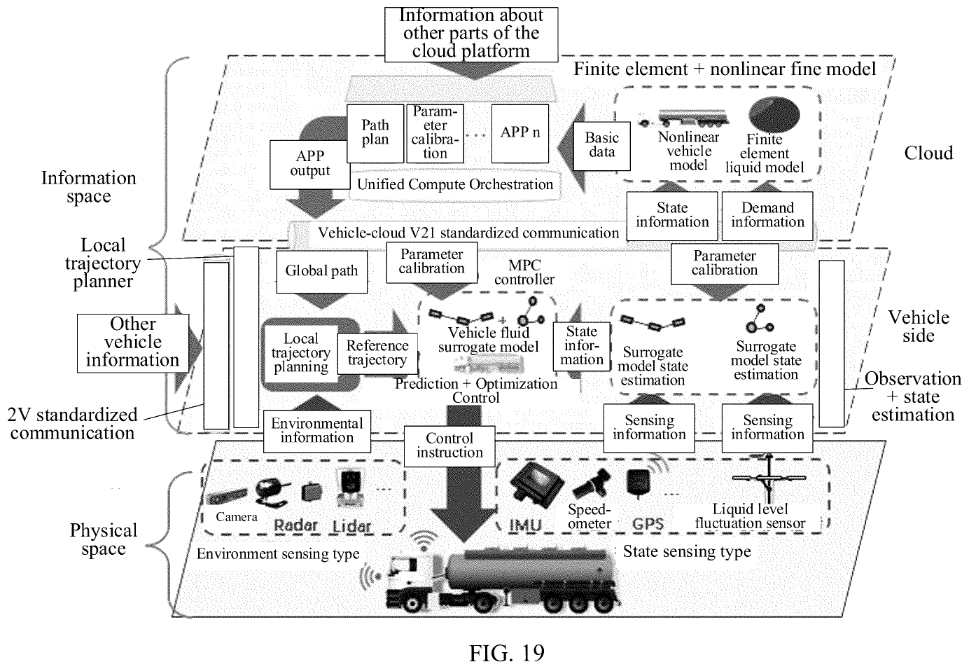

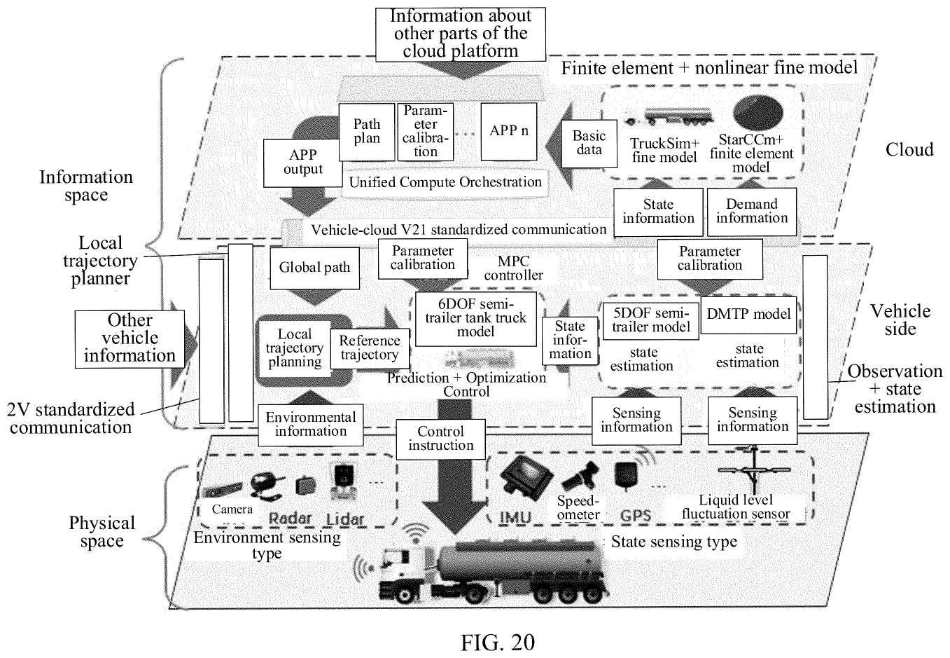

The method for controlling rollover prevention of the tank truck according to the specific embodiment is described below in conjunction with FIG. 19, and a schematic diagram of specific expansion is illustrated in FIG. 20, and includes the following steps.

In step 1, the vehicle fine model and the liquid sloshing fine model established by the cloud are adjusted by the cloud based on the vehicle information sent by the vehicle side and the liquid filling information obtained based on the sensor. Parameter calibration calculation of the vehicle surrogate model and the liquid surrogate model required by the vehicle side is performed based on calculation results of fine models. Parameter calibration results are transmitted to the vehicle side. Preferably, the vehicle fine model is a multi-body dynamics model, which is preferably established using TruckSim software. Preferably, the liquid sloshing fine model is a finite element model, which is preferably established using StarCCM+ software. Preferably, the vehicle surrogate model is a linear simplified dynamics model. Preferably, the liquid surrogate model is an equivalent pendulum dynamics model.

In step 2, a state variable of the vehicle surrogate model required for control is estimated by a vehicle side observation and state estimator based on vehicle state sensor information observation. A state variable of the liquid surrogate model required for control is estimated by the vehicle side observation and state estimator based on the liquid related sensor information observation. Preferably, the vehicle state sensor includes GPS, IMU, a wheel speed sensor, and the like. Preferably, the liquid-related sensor may be a free liquid level fluctuation sensor, which can ensure real-time measurement of an average inclination angle of a liquid surface and a liquid level under a static state.

In step 3, the vehicle-side controller performs control based on a control target according to the state variable information in the step 2. Preferably, the controller is a multi-constraint MPC controller. Preferably, the control target is trajectory tracking plus sway suppression plus rollover prevention.

In step 4, the step 2 and the step 3 are repeated, and other vehicle-cloud collaborative control tasks, such as global path planning, cloud-controlled predictive cruise, are synchronously performed.

In summary, with the method for controlling rollover prevention of the tank truck in the present disclosure, by establishing a more accurate model and using cloud computing, accurate model parameters that may be configured to realize model predictive control are obtained. Compared with model-free adaptive control (MFAC), the vehicle and the liquid dynamic state may be predicted in advance, which further prevents the vehicle from entering a dangerous state, instead of rescuing the vehicle after entering the dangerous state. Making full use of characteristics of a large computation power of the cloud and high real-time performance of the vehicle side, a vehicle-cloud collaborative control architecture of cloud finite element calibration plus vehicle-side real-time control is developed based on the vehicle-cloud collaborative control architecture.

An apparatus for controlling rollover prevention of a tank truck according to the embodiments of the present disclosure is described below with reference to the accompanying drawings.

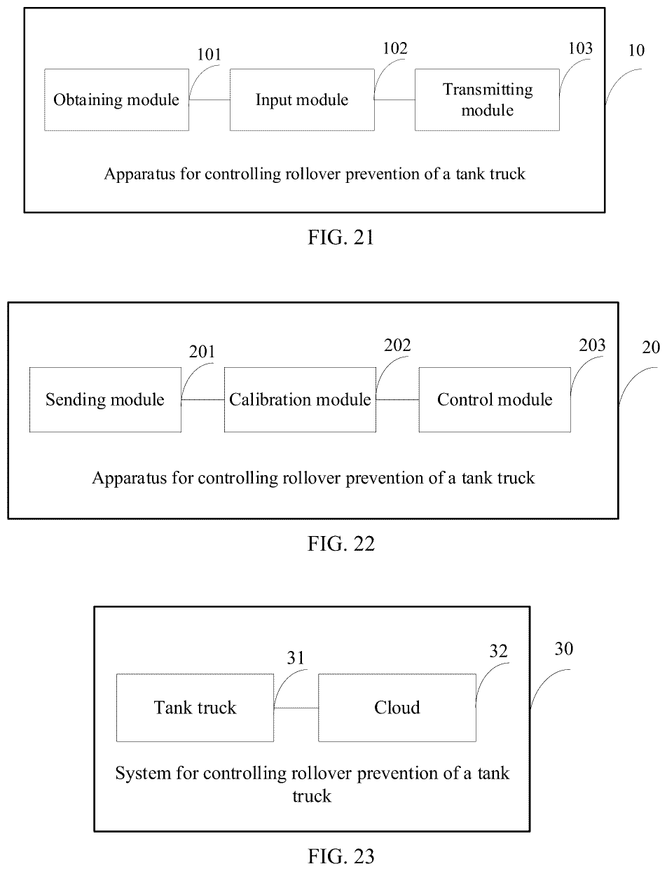

FIG. 21 is a schematic block diagram of an apparatus for controlling rollover prevention of a tank truck according to an embodiment of the present disclosure.

As illustrated in FIG. 21, the apparatus 10 for controlling rollover prevention of the tank truck is applied to the cloud and includes an obtaining module 101, an input module 102, and a transmitting module 103.

The obtaining module 101 is configured to obtain vehicle information sent by the tank truck and liquid filling information obtained based on a sensor. The input module 102 is configured to input the vehicle information and the liquid filling information into a vehicle fine model and a liquid sloshing fine model respectively. The vehicle fine model outputs a first parameter calibration result, and the liquid sloshing fine model outputs a second parameter calibration result. The transmitting module 103 is configured to transmit the first parameter calibration result and the second parameter calibration result to the tank truck. The tank truck calibrates a vehicle surrogate model and a liquid surrogate model by using the first parameter calibration result and the second parameter calibration result respectively, determines a control target of the tank truck by combining vehicle state sensor information observation and liquid related sensor information observation, and controls the rollover prevention of the tank truck based on the control target.

In the embodiment of the present disclosure, the vehicle fine model is a multi-body dynamics model. The liquid sloshing fine model is a finite element model. The vehicle surrogate model is a linear simplified dynamics model. The liquid surrogate model is an equivalent pendulum dynamics model.

In the embodiment of the present disclosure, the input module 102 further includes: an obtaining unit configured to obtain, prior to the vehicle information and the liquid filling information are inputted into the vehicle fine model and the liquid sloshing fine model respectively, a multi-degree-of-freedom equivalent pendulum model of liquid sloshing in a tank of the tank truck; a setting unit configured to set a specific structure and an input variable of the multi-degree-of-freedom equivalent pendulum model, and determine kinetic energy and potential energy of the multi-degree-of-freedom equivalent pendulum model based on the specific structure and the input variable; an determining unit configured to determine a differential dynamics equation of a plurality of swing degrees of freedom based on the kinetic energy and the potential energy of the multi-degree-of-freedom equivalent pendulum model, and identify all undetermined parameters of the differential dynamics equation based on an established liquid sloshing model for a cross-section of the tank; and a constructing unit configured to construct a simplified liquid sloshing model for the tank of the tank truck based on the differential dynamics equation and all the undetermined parameters.

In the embodiment of the present disclosure, the obtaining unit is further configured to: take a pendulum rod and a lumped mass as basic units; hinge an end of the pendulum rod to a point or a lumped mass in the cross-section of the tank; determine a motion track of the lumped mass connected by the pendulum rod without a fixing end as a part of an ellipse; and allow the lumped mass to hinge a plurality of pendulum rods, and allow one or more lumped masses to be fixed to a point in the cross-section of the tank with the one or more lumped masses not connecting any pendulum rod to establish the multi-degree-of-freedom equivalent pendulum model.

In a specific embodiment of the present disclosure, the specific structure includes a linear and/or non-linear combination of at least a plurality of simple pendulums and/or elliptical pendulums.

In the embodiment of the present disclosure, the setting unit is further configured to: set an acting point and a positive direction of an output force and a torque of the multi-degree-of-freedom equivalent pendulum model in the cross-section of the tank, and establish a plane rectangular coordinate system by taking the acting point as an origin and taking the positive direction as a coordinate axis; express a position vector of each lumped mass of the multi-degree-of-freedom equivalent pendulum model in the plane rectangular coordinate system, and calculate a first derivative and a second derivative of the position vector of each lumped mass with respect to time to obtain a velocity vector and an acceleration vector of each lumped mass; and determine the kinetic energy of the multi-degree-of-freedom equivalent pendulum model and potential energy of the kinetic energy of the multi-degree-of-freedom equivalent pendulum model at a designated zero potential energy point by using the position vector, the velocity vector, and the acceleration vector.

In the embodiment of the present disclosure, a plurality of output variables of the liquid sloshing model and an output mode for the output variables are set. Output variable time series data of the plurality of output variables is obtained based on a predetermined operation condition, and a cost function of an undetermined parameter of the differential dynamics equation is constructed based on the output mode for the output variables and the output variable time series data. The cost function is optimized and all undetermined parameters of the differential dynamics equation are identified based on the optimized cost function.

In the embodiment of the present disclosure, the output variables include a lateral force, a vertical force, and a roll torque. The predetermined operation condition includes a lateral acceleration step excitation operation condition and/or a lateral acceleration sinusoid fluctuation operation condition. The cost function is a non-negative weighted sum of all error terms.

It should be noted that, the foregoing explanation of the embodiments of the method for controlling rollover prevention of the tank truck is also applicable to the apparatus for controlling rollover prevention of the tank truck of the embodiments, and thus details thereof will be omitted here.

With the apparatus for controlling rollover prevention of the tank truck according to the embodiments of the present disclosure, a calculation advantage of a high computation power of the cloud may be utilized to obtain more accurate model parameter calibration results. The model parameter calibration results are transmitted to the vehicle side for realizing model predictive control, which can predict the vehicle and the liquid dynamic state in advance, preventing the vehicle from entering the dangerous state.

As illustrated in FIG. 22, the apparatus 10 for controlling rollover prevention of the tank truck is applied to the tank truck and includes a sending module 201, a calibration module 202, and a control module 203.

The sending module 201 is configured to send vehicle information and liquid filling information obtained based on a sensor to a cloud. The cloud inputs the vehicle information and the liquid filling information into a vehicle fine model and a liquid sloshing fine model respectively, and the vehicle fine model outputs a first parameter calibration result and the liquid sloshing fine model outputs a second parameter calibration result. The calibration module 202 is configured to obtain the first parameter calibration result and the second parameter calibration result transmitted from the cloud, and calibrate a vehicle surrogate model and a liquid surrogate model by using the first parameter calibration result and the second parameter calibration result respectively. The control module 203 is configured to determine a control target of the tank truck by combining vehicle state sensor information observation and liquid related sensor information observation, and control the rollover prevention of the tank truck based on the control target.

In the embodiment of the present disclosure, the control module 300 is further configured to: estimate a first state variable of the vehicle surrogate model based on the vehicle state sensor information observation; estimate a second state variable of the liquid surrogate model based on the liquid related sensor information observation; and determine the control target of the tank truck based on the first state variable and the second state variable. In the embodiment of the present disclosure, the control module 300 is further

configured to: obtain a first reference value of the vehicle surrogate model and a second reference value of the liquid surrogate model; determine a first error weight between an output variable of the vehicle surrogate model and the first reference value and a second error weight between an output variable of the liquid surrogate model and the second reference value; and apply the first error weight to the output variable of the vehicle surrogate model to realize a control target of trajectory tracking, apply the second error weight to the output variable of the liquid surrogate model to realize a control target of sway suppression, and perform a soft constraint on a range of a part of output variables of the liquid surrogate model to realize a control target of rollover prevention.

In the embodiment of the present disclosure, the part of output variables to which the soft constraint is applied at least includes Iᵣₒₗₗₒᵥₑᵣ. The output variable of the liquid surrogate model is y=[X₁ Y₁ ψ₁ θ \dot{θ} Iᵣₒₗₗₒᵥₑᵣ], where X represents an x coordinate of a tractor in a world coordinate system, Y represents a y coordinate of the tractor in the world coordinate system, θ represents a swing angle of an equivalent pendulum model, \dot{θ} represents a swing angular velocity of the equivalent pendulum model, Iᵣₒₗₗₒᵥₑᵣ represents a state variable representing a rollover state of a vehicle, represents a heading angle of the tractor.

In the embodiment of the present disclosure, the state variable Iᵣₒₗₗₒᵥₑᵣ representing the rollover state of the vehicle uses a lateral load transfer ratio LTR_{eql} equivalent to a suspension force:

$${LTR}_{eql} = \frac{2}{\frac{{T}_{w 1} + {T}_{w 2}}{2} ( {m}_{1} + {m}_{2} ) g} ( - {k}_{r 1} {ϕ}_{1} - {c}_{1} {\dot{ϕ}}_{1} - {k}_{r 2} {ϕ}_{2} - {c}_{2} {\dot{ϕ}}_{2} ) ,$$

where T_{w} represents an average track length of each axle, m represents a mass of the vehicle, g represents an acceleration of gravity, k, represents roll angle stiffness, c represents roll damping, ϕ represents a roll angle, \dot{ϕ} represents roll angular velocity, a subscript 1 represents the tractor, and a subscript 2 represents a trailer.

It should be noted that, the foregoing explanation of the embodiments of the method for controlling rollover prevention of the tank truck is also applicable to the apparatus for controlling rollover prevention of the tank truck of the embodiments, and thus details thereof will be omitted here.

With the apparatus for controlling rollover prevention of the tank truck according to the embodiment of the present disclosure, by using the advantage of high real-time performance of the vehicle side, the vehicle information and the liquid filling information of the tank truck are transmitted to the cloud in real time. Further, the model processing data of the cloud is controlled to receive the model parameter calibration results transmitted from the cloud. By using the model predictive control of the vehicle side, the tank truck and the liquid dynamic state are predicted in advance, which prevents the tank truck from entering the dangerous state.

A cloud is provided by the embodiments of the present disclosure. The cloud includes a memory, a processor, and a computer program stored in the memory and executable on the processor. The processor executes the computer program to implement the method for controlling rollover prevention of the tank truck according to above embodiments.

A tank truck is further provided by the embodiments of the present disclosure. The tank truck includes a memory, a processor, and a computer program stored in the memory and executable on the processor. The processor executes the computer program to implement the method for controlling rollover prevention of the tank truck according to above embodiments.

A system for controlling rollover prevention of a tank truck according to the embodiments of the present disclosure is described below with reference to the accompanying drawings.

As illustrated in FIG. 23, a system 30 for controlling rollover prevention of a tank truck includes the tank truck 31 and a cloud 32.

The tank truck includes a sensor, a communication device, and a vehicle calculation unit. The communication device communicates with a cloud. The vehicle calculation unit, internally including an observation and state estimator and a controller, obtains state variables related to a vehicle and liquid by using sensor data and a surrogate model, and controls the rollover prevention of the tank truck by using the surrogate model. The cloud includes a cloud information space and provides a parameter calibration service for the surrogate model by using a vehicle fine model and a liquid sloshing fine model that are digital twins of the surrogate model.

It should be understood that, according to the embodiment of the present disclosure, the tank truck communicates with the cloud through the communication device, obtains the state variables related to the vehicle and the liquid through the sensor and the surrogate model, and controls the rollover prevention of the tank truck by using the surrogate model. The cloud includes the cloud information space, provides the parameter calibration service for the surrogate model by using the vehicle fine model and the liquid sloshing fine model that are digital twins of the surrogate model, and obtains more accurate model parameters. Hardware in the physical world, such as a controlled tank truck, an actuator, the sensor, and the communication device, is configured to perform transportation tasks, measure states of the vehicle and the liquid, sense the surrounding environment, and communicate with the cloud and surrounding vehicles, etc.

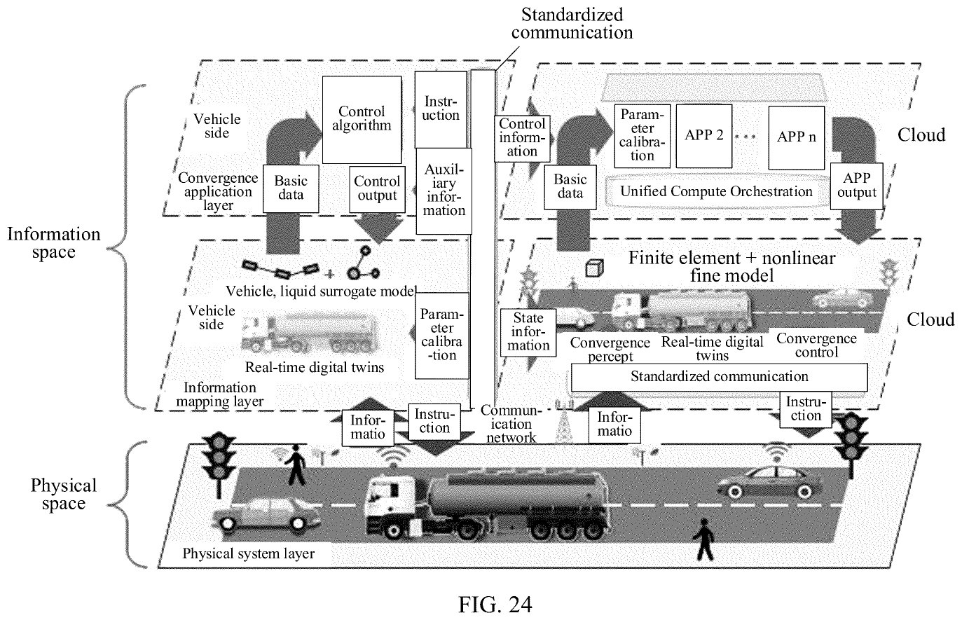

In an exemplary embodiment of the present disclosure, as illustrated in FIG. 24, the system for controlling rollover prevention of the tank truck according to the embodiment of the present disclosure is a collaborative control architecture based on cloud finite element calibration plus vehicle-side surrogate model real-time control.

The architecture includes an information space and a physical space. The physical space contains controlled passenger tank trucks and other traffic participants. The information space consists of two layers, an information mapping layer and a convergence application layer, both of which are distributed in each of the vehicle side and the cloud. In the information mapping layer, the vehicle side contains simple digital twins about the vehicle and composed of the vehicle surrogate model and the liquid surrogate model. The cloud contains fine model digital twins with the tank truck and digital twins of other traffic participants. The convergence application layer is distributed in a vehicle-side controller and a cloud server. In the vehicle-side controller, the controller performs model predictive control based on digital twin data of a simple vehicle surrogate model at the vehicle side.

The embodiments of the present disclosure further provide a computer-readable storage medium having a computer program stored thereon. The computer program, when executed by a processor, implements the method for controlling rollover prevention of the tank truck according to the above embodiments.

Reference throughout this specification to “an embodiment”, “some embodiments”, “an example”, “a specific example”, or “some examples” means that a particular feature, structure, material, or characteristic described in connection with the embodiment or example is included in at least one embodiment or example of the present disclosure. The appearances of the above phrases in various places throughout this specification are not necessarily referring to the same embodiment or example. Further, the particular features, structures, materials, or characteristics may be combined in any suitable manner in one or N embodiments or examples. In addition, different embodiments or examples and features of different embodiments or examples described in the specification may be combined by those skilled in the art without mutual contradiction.

In addition, the terms “first” and “second” are only used for descriptive purposes, and cannot be understood as indicating or implying relative importance or implicitly indicating the number of indicated technical features. Therefore, the features associated with “first” and “second” may explicitly or implicitly include at least one of the features. In the description of the present disclosure, “N” means at least two, such as two, three, unless otherwise specifically defined.

Any process or method described in a flowchart or described herein in other ways may be understood to include one or N modules, segments, or portions of codes of executable instructions for achieving specific logical functions or steps in the process. The scope of a preferred embodiment of the present disclosure includes other implementations. A function may be performed not in a sequence shown or discussed, including a substantially simultaneous manner or a reverse sequence based on the function involved, which should be understood by those skilled in the art to which the embodiments of the present disclosure belong.

It should be understood that each part of the present disclosure may be realized by hardware, software, firmware, or a combination thereof. In the above embodiments, N steps or methods may be realized by software or firmware stored in the memory and executed by an appropriate instruction execution system. For example, when it is realized by the hardware, likewise in another embodiment, the steps or methods may be realized by one or a combination of the following techniques known in the art: a discrete logic circuit having a logic gate circuit for realizing a logic function of a data signal, an application-specific integrated circuit having an appropriate combination logic gate circuit, a Programmable Gate Array, a Field Programmable Gate Array, etc.

It should be understood by those skilled in the art that all or a part of the steps carried by the method in the above-described embodiments may be completed by relevant hardware instructed by a program. The program may be stored in a computer-readable storage medium. When the program is executed, one or a combination of the steps of the method in the above-described embodiments may be included.

Although embodiments of the present disclosure have been illustrated and described above, it should be understood that the above embodiments are merely exemplary, and cannot be construed to limit the present disclosure. For those skilled in the art, changes, modifications, alternatives, and variants can be made to the embodiments without departing from the scope of the present disclosure.

What is claimed is:

1. A method for controlling rollover prevention of a tank truck, wherein the method is applied to a cloud and comprises:
obtaining vehicle information sent by the tank truck and liquid filling information obtained based on a sensor;
inputting the vehicle information and the liquid filling information into a vehicle fine model and a liquid sloshing fine model respectively, wherein the vehicle fine model outputs a first parameter calibration result, and the liquid sloshing fine model outputs a second parameter calibration result; and
transmitting the first parameter calibration result and the second parameter calibration result to the tank truck, wherein the tank truck calibrates a vehicle surrogate model and a liquid surrogate model by using the first parameter calibration result and the second parameter calibration result respectively, determines a control target of the tank truck by combining vehicle state sensor information observation and liquid related sensor information observation, and controls the rollover prevention of the tank truck based on the control target.

2. The method for controlling rollover prevention of the tank truck according to claim 1, wherein:
the vehicle fine model is a multi-body dynamics model, and the liquid sloshing fine model is a finite element model, and
the vehicle surrogate model is a linear simplified dynamics model, and the liquid surrogate model is an equivalent pendulum dynamics model.

3. The method for controlling rollover prevention of the tank truck according to claim 1, wherein the method further comprises, prior to inputting the vehicle information and the liquid filling information into the vehicle fine model and the liquid sloshing fine model respectively:
obtaining a multi-degree-of-freedom equivalent pendulum model of liquid sloshing in a tank of the tank truck;
setting a specific structure and an input variable of the multi-degree-of-freedom equivalent pendulum model, and determining kinetic energy and potential energy of the multi-degree-of-freedom equivalent pendulum model based on the specific structure and the input variable;
determining a differential dynamics equation of a plurality of swing degrees of freedom based on the kinetic energy and the potential energy of the multi-degree-of-freedom equivalent pendulum model, and identifying all undetermined parameters of the differential dynamics equation based on an established liquid sloshing model for a cross-section of the tank; and
constructing a simplified liquid sloshing model for the tank of the tank truck based on the differential dynamics equation and all the undetermined parameters.

4. The method for controlling rollover prevention of the tank truck according to claim 3, wherein said obtaining the multi-degree-of-freedom equivalent pendulum model of liquid sloshing in the tank of the tank truck comprises:
taking a pendulum rod and a lumped mass as basic units;
hinging an end of the pendulum rod to a point or a lumped mass in the cross-section of the tank;
determining a motion track of the lumped mass connected by the pendulum rod without a fixing end as a part of an ellipse; and
allowing the lumped mass to hinge a plurality of pendulum rods, and allowing one or more lumped masses to be fixed to a point in the cross-section of the tank with the one or more lumped masses not connecting any pendulum rod to establish the multi-degree-of-freedom equivalent pendulum model.

5. The method for controlling rollover prevention of the tank truck according to claim 4, wherein the specific structure comprises a linear and/or non-linear combination of at least a plurality of simple pendulums and/or elliptical pendulums.

6. The method for controlling rollover prevention of the tank truck according to claim 3, wherein said determining the kinetic energy and potential energy of the multi-degree-of-freedom equivalent pendulum model based on the specific structure and the input variable comprises:
setting an acting point and a positive direction of an output force and a torque of the multi-degree-of-freedom equivalent pendulum model in the cross-section of the tank, and establishing a plane rectangular coordinate system by taking the acting point as an origin and taking the positive direction as a coordinate axis;
expressing a position vector of each lumped mass of the multi-degree-of-freedom equivalent pendulum model in the plane rectangular coordinate system, and calculating a first derivative and a second derivative of the position vector of each lumped mass with respect to time to obtain a velocity vector and an acceleration vector of each lumped mass; and
determining the kinetic energy of the multi-degree-of-freedom equivalent pendulum model and potential energy of the kinetic energy of the multi-degree-of-freedom equivalent pendulum model at a designated zero potential energy point by using the position vector, the velocity vector, and the acceleration vector.

7. The method for controlling rollover prevention of the tank truck according to claim 3, wherein said identifying all undetermined parameters of the differential dynamics equation based on the established liquid sloshing model for the cross-section of the tank comprises:
setting a plurality of output variables of the liquid sloshing model and an output mode for the output variables;
obtaining output variable time series data of the plurality of output variables based on a predetermined operation condition, and constructing a cost function of an undetermined parameter of the differential dynamics equation based on the output mode for the output variables and the output variable time series data; and
optimizing the cost function and identifying all undetermined parameters of the differential dynamics equation based on the optimized cost function.

8. The method for controlling rollover prevention of the tank truck according to claim 7, wherein:
the output variables comprise a lateral force, a vertical force, and a roll torque;
the predetermined operation condition comprises a lateral acceleration step excitation operation condition and/or a lateral acceleration sinusoid fluctuation operation condition, and the cost function is a non-negative weighted sum of all error terms.

9. A method for controlling rollover prevention of a tank truck, wherein the method is applied to the tank truck and comprises:
sending vehicle information and liquid filling information obtained based on a sensor to a cloud, wherein the cloud inputs the vehicle information and the liquid filling information into a vehicle fine model and a liquid sloshing fine model respectively, and wherein the vehicle fine model outputs a first parameter calibration result and the liquid sloshing fine model outputs a second parameter calibration result;
obtaining the first parameter calibration result and the second parameter calibration result transmitted from the cloud, calibrating a vehicle surrogate model and a liquid surrogate model by using the first parameter calibration result and the second parameter calibration result respectively; and
determining a control target of the tank truck by combining vehicle state sensor information observation and liquid related sensor information observation, and controlling the rollover prevention of the tank truck based on the control target.

10. The method for controlling rollover prevention of the tank truck according to claim 9, wherein said determining the control target of the tank truck by combining the vehicle state sensor information observation and the liquid related sensor information observation comprises:
estimating a first state variable of the vehicle surrogate model based on the vehicle state sensor information observation;
estimating a second state variable of the liquid surrogate model based on the liquid related sensor information observation; and
determining the control target of the tank truck based on the first state variable and the second state variable.

11. The method for controlling rollover prevention of the tank truck according to claim 9, wherein said controlling the rollover prevention of the tank truck based on the control target comprises:
obtaining a first reference value of the vehicle surrogate model and a second reference value of the liquid surrogate model;
determining a first error weight between an output variable of the vehicle surrogate model and the first reference value and a second error weight between an output variable of the liquid surrogate model and the second reference value; and
applying the first error weight to the output variable of the vehicle surrogate model to realize a control target of trajectory tracking, applying the second error weight to the output variable of the liquid surrogate model to realize a control target of sway suppression, and performing a soft constraint on a range of a part of output variables of the liquid surrogate model to realize a control target of rollover prevention.

12. The method for controlling rollover prevention of the tank truck according to claim 11, wherein:
the part of output variables to which the soft constraint is applied at least comprises Iᵣₒₗₗₒᵥₑᵣ;
the output variable of the liquid surrogate model is y=[X₁ Y₁ ψ₁ θ \dot{θ} Iᵣₒₗₗₒᵥₑᵣ],
where X represents an x coordinate of a tractor in a world coordinate system, Y represents a y coordinate of the tractor in the world coordinate system, θ represents a swing angle of an equivalent pendulum model, \dot{θ} represents a swing angular velocity of the equivalent pendulum model, Iᵣₒₗₗₒᵥₑᵣ represents a state variable representing a rollover state of a vehicle, ψ₁ represents a heading angle of the tractor.

13. The method for controlling rollover prevention of the tank truck according to claim 12, wherein: the state variable Iᵣₒₗₗₒᵥₑᵣ representing the rollover state of the vehicle uses a lateral load transfer ratio LTR_{eql} equivalent to a suspension force:
$${LTR}_{eql} = \frac{2}{\frac{{T}_{w 1} + {T}_{w 2}}{2} ( {m}_{1} + {m}_{2} ) g} ( - {k}_{r 1} {ϕ}_{1} - {c}_{1} {\dot{ϕ}}_{1} - {k}_{r 2} {ϕ}_{2} - {c}_{2} {\dot{ϕ}}_{2} )$$
where T_{w} represents an average track length of each axle, m represents a mass of the vehicle, g represents an acceleration of gravity, kᵣ represents roll angle stiffness, c represents roll damping, ϕ represents a roll angle, \dot{ϕ} represents roll angular velocity, a subscript 1 represents the tractor, and a subscript 2 represents a trailer.

14. A cloud, comprising:
a memory;
a processor; and
a computer program stored in the memory and executable on the processor,
wherein the processor executes the computer program to implement the method for controlling rollover prevention of the tank truck according to claim 1.

15. A tank truck, comprising:
a memory;
a processor; and
a computer program stored in the memory and executable on the processor,
wherein the processor executes the computer program to implement the method for controlling rollover prevention of the tank truck according to claim 9.

16. A system for controlling rollover prevention of a tank truck, comprising:
a tank truck comprising a sensor, a communication device, and a vehicle calculation unit, wherein the communication device communicates with a cloud, and the vehicle calculation unit, internally comprising an observation and state estimator and a controller, obtains state variables related to a vehicle and liquid by using sensor data and a surrogate model, and controls the rollover prevention of the tank truck by using the surrogate model; and
a cloud comprising a cloud information space and providing a parameter calibration service for the surrogate model by using a vehicle fine model and a liquid sloshing fine model that are digital twins of the surrogate model.

17. A computer-readable storage medium, having a computer program stored thereon, wherein the computer program is executed by a processor to implement the method for controlling rollover prevention of the tank truck according to claim 1.

18. A computer-readable storage medium, having a computer program stored thereon, wherein the computer program is executed by a processor to implement the method for controlling rollover prevention of the tank truck according to claim 9.
